(19) United States
(12) Patent Application Publication
(10) Pub. No.: US 2026/0129809 A1
(43) Pub. Date: May 7, 2026

(54) DATACENTER COOLING SYSTEMS THAT INCLUDE PRESSURE EXCHANGERS

(71) Applicant: Energy Recovery, Inc., San Leandro, CA (US)

(72) Inventor: Azam Mihir Thatte, Kensington, CA (US)

(21) Appl. No.: 19/117,469

(22) PCT Filed: Oct. 6, 2023
(86) PCT No.: PCT/US2023/034649

§ 371 Date: Apr. 1, 2025

Related U.S. Application Data
(60) Provisional application No. 63/414,117, filed on Oct. 7, 2022.

(51) Int. Cl. H05K 7/20; G06F 1/20

(52) U.S. Cl. CPC H05K 7/20827; G06F 1/20; H05K 7/20309; H05K 7/20327; H05K 7/20354; G06F 2200/201; H05K 7/20318

(57) ABSTRACT

A system includes a refrigeration system to exchange heat between a first cooling loop and a second cooling loop. The refrigeration system includes a pressure exchanger (310) that is to receive a first fluid at a first pressure and a second fluid at a second pressure and exchange pressure between the first fluid and the second fluid. The refrigeration system further includes a first heat exchanger (318) to exchange heat between the first cooling loop and a portion of the first fluid output from the pressure exchanger. The refrigeration system further includes a second heat exchanger (329) to exchange heat between a portion of the first fluid that is to enter the pressure exchanger and the second cooling loop.

### TECHNICAL FIELD

The present disclosure relates to systems, and, more particularly, datacenter cooling systems that include pressure exchangers.

### BACKGROUND

Systems use fluids at different pressures. Systems use pumps or compressors to increase pressure of fluid.

### BRIEF DESCRIPTION OF THE DRAWINGS

The present disclosure is illustrated by way of example, and not by way of limitation in the figures of the accompanying drawings.

FIGS. 1A-1C illustrate schematic diagrams of fluid handling systems including hydraulic energy transfer systems, according to certain embodiments.

FIGS. 2A-2E are exploded perspective views of pressure exchangers (PXs), according to certain embodiments.

FIGS. 3A-3C are schematic diagrams of datacenter cooling systems including pressure exchangers, according to certain embodiments.

FIG. 4 is a schematic diagram of a datacenter cooling system including a pressure exchanger, according to certain embodiments.

FIGS. 5A-5F are schematic diagrams of datacenter cooling systems including pressure exchangers, according to certain embodiments.

FIG. 6 is a flow diagram illustrating an example method for controlling a datacenter cooling system, according to certain embodiments.

FIG. 7 is a block diagram illustrating a computer system, according to certain embodiments.

### DETAILED DESCRIPTION OF EMBODIMENTS

Embodiments described herein are related to datacenter cooling systems that include a pressure exchanger (e.g., datacenter cooling systems, fluid handling systems, heat transfer systems, pressure exchanger systems, carbon dioxide (CO₂) refrigeration systems, etc.).

Systems may use fluids at different pressures. These systems may include hydraulic fracturing (e.g., fracking or fracing) systems, desalinization systems, refrigeration systems, air conditioning systems, datacenter cooling systems, heat pump systems, energy generation systems, mud pumping systems, slurry pumping systems, industrial fluid systems, waste fluid systems, fluid transportation systems, etc. Pumps or compressors may be used to increase pressure of fluid to be used by systems.

Conventionally, refrigeration and/or air conditioning systems use compressors to increase the pressure of a fluid (e.g., a refrigeration fluid such as CO₂, R-134a, hydrocarbons, hydrofluorocarbons (HFCs), hydrochlorofluorocarbons (HCFCs), ammonia (NH₃), refrigerant blends, R-407A, R-404A, etc.). Conventionally, separate compressors mechanically coupled to motors are used to increase pressure of the fluid. Pumps and compressors that operate over a large pressure differential (e.g., cause a large pressure increase in the fluid) use large quantities of energy. Conventional systems thus expend large amounts of energy increasing the pressure of the fluid (via the pumps or compressors driven by the motors). Additionally, conventional refrigeration systems decrease the pressure of the fluid through expansion valves.

While fluid of conventional refrigeration systems decreases pressure (e.g., expands, etc.) through an expansion valve, no useful work is extracted from the expanding fluid, thus introducing an energy inefficiency into the conventional systems. Further, hydrofluorocarbon (HFC) refrigerants (e.g. R-134a, R-404a, etc.) allegedly contribute to climate change and are being phased out by several countries. Conventional HFC refrigerants are being replaced by natural refrigerants such as CO₂ (e.g., R-744) which has negligible impact on the environment. However, the operating pressure for refrigeration systems that use CO₂as the refrigerant is much higher than for refrigeration systems using HFC refrigerants (e.g., 900 psi to 1,500 psi, compared to 200 psi to 300 psi, etc.). Thus, refrigeration systems using CO₂ refrigerant may consume significantly more energy compared to conventional refrigeration systems using HFC refrigerants. Refrigeration systems using CO₂ refrigerant experience increased energy consumption when operated in warmer ambient conditions because pressure increases in the gas cooler/condenser as the ambient temperature increases, and thus the compressor performs more work to overcome the increase in pressure. This is one of the key challenges associated with CO₂ refrigeration systems. The systems of the present disclosure solve this challenge by extracting energy during expansion of the high pressure CO₂ refrigerant and using the expanding refrigerant to compress a portion of the refrigerant flow, which may reduce the energy consumption of the main compressor of the refrigeration system.

Air conditioning systems (e.g., refrigeration systems, etc.) are often used for datacenter cooling. Conventional air conditioning systems can be used to cool air that is provided inside a datacenter computer room to cool computer components such as servers and/or server components. However, conventional air conditioning systems used for datacenter cooling suffer the same shortcomings as described above, particularly the inefficiencies during expansion of refrigerant over large pressure differentials. A large amount of energy is used to operate conventional air conditioning systems for datacenter cooling. This problem is exacerbated by the increasing size of datacenters and the increasing computing power of new computing components leading to increased heat output. The increased heat output of computing components having increased computing power and/or the increased datacenter size necessitates increased cooling capacity that cannot be efficiently provided using conventional air conditioning systems.

The systems, devices, and methods of the present disclosure provide datacenter cooling systems (e.g., datacenter refrigeration systems, etc.). In some embodiments, a datacenter cooling system includes a refrigeration system to exchange heat between a first cooling loop and a second cooling loop. The first cooling loop may flow a first heat transfer fluid or a coolant (e.g., such as water or a water-glycol mixture, etc.) to cool multiple servers (e.g., computing units, computing components, server components, etc.) disposed in a datacenter server room (e.g., a datacenter room, etc.). In some embodiments, the first cooling loop is configured to cool air in the datacenter. For example, the first cooling loop may cool a flow of air in the datacenter server room (e.g., computer room, etc.) via a cooling coil (e.g., a cooling coil of a computer room air conditioner, etc.). Warm air from the servers may flow over the cooling coil (e.g., may be blown by a fan over the cooling coil). The warm air may be cooled and the cooled air may be circulated in the server room back to the servers to cool the servers. Heat from the servers may be transferred from the warm air to the first cooling loop (e.g., via the cooling coil).

In some embodiments, the first cooling loop provides the heat from the servers to the refrigeration system (e.g., a datacenter cooling system having a pressure exchanger as described herein). In some embodiments, the refrigeration system provides the heat from the servers to the second cooling loop. The second cooling loop may flow a second heat transfer fluid or a coolant (e.g., such as water or a water-glycol mixture, etc.) to a cooling tower and/or a chiller unit. In some embodiments, the cooling tower or chiller unit is to reject the heat from the second cooling loop to an ambient environment (e.g., a heat sink, etc.).

In some embodiments, the refrigeration system (e.g., datacenter cooling system, heat transfer system, CO₂ refrigeration system, etc.) flows a refrigerant (e.g., CO₂ refrigerant or other suitable refrigerant, etc.) along a refrigeration cycle. In some embodiments, the refrigeration system includes a pressure exchanger (PX) that is configured to exchange pressure between a first fluid (e.g., a high pressure portion of the refrigeration fluid in a refrigeration cycle) and a second fluid (e.g., a low pressure portion of the refrigeration fluid in the refrigeration cycle). In some embodiments, the PX may receive a first fluid (e.g., a portion of the refrigeration fluid at high pressure) via a first inlet (e.g., a high pressure inlet) and a second fluid (e.g., a portion of the refrigeration fluid at a low pressure.) via a second inlet (e.g., a low pressure inlet). In some embodiments, the first fluid is received at the first inlet at a high pressure from the second heat exchanger. When entering the PX, the first fluid may have a higher pressure than the second fluid. The PX may exchange pressure between the first fluid and the second fluid. The first fluid may exit the PX via a first outlet (e.g., a low pressure outlet) and the second fluid may exit the PX via a second outlet (e.g., a high pressure outlet). In some embodiments, the second fluid is provided from the second outlet to the first heat exchanger. When exiting the PX, the second fluid may have a higher pressure than the first fluid (e.g., due to the pressure exchange between the first fluid and the second fluid).

In some embodiments, the datacenter cooling system includes a first heat exchanger to exchange heat between the first cooling loop and the refrigeration system. The first cooling loop may provide the heat from the multiple servers to the first heat exchanger, where the heat may then be provided to the refrigeration system (e.g., the heat is transferred from the first cooling loop to the refrigeration fluid in the first heat exchanger). The first heat exchanger may be an evaporator (e.g., to evaporate refrigerant from a liquid state to a gas state, etc.). In some embodiments, the first heat exchanger exchanges heat between the fluid of the first cooling loop and at least a portion of the first fluid output from the first outlet of the PX. The first heat exchanger may exchange heat between coolant of the first cooling loop and at least a portion of refrigeration fluid output from the first outlet of the PX. In some embodiments, the datacenter cooling system includes a second heat exchanger to exchange heat between the refrigeration system and the second cooling loop. The refrigeration system may provide the heat from the multiple servers to the second heat exchanger, where the heat may then be provided to the second cooling loop. In some embodiments, the second heat exchanger exchanges heat between at least a portion of the first fluid that is to enter the first inlet of the PX and the fluid of the second cooling loop. The second heat exchanger may be a gas cooler (e.g., to cool refrigerant in a gas state) or a condenser (e.g., to condense refrigerant from a gas state to a liquid state). The second cooling loop may carry the heat away to the cooling tower and/or chiller unit for disposal of the heat.

The systems, devices, and methods of the present disclosure have advantages over conventional solutions. The systems of the present disclosure may use a reduced amount of energy (e.g., use less energy to provide datacenter cooling, etc.) compared to conventional systems. The PX may allow for the recovery of energy (e.g., pressure energy, etc.) in the refrigeration system that is ordinarily lost in conventional systems. The recovered energy may be used to compress a portion of the refrigerant (e.g., in a vapor state) to high pressure (e.g. the operating pressure of the condenser or gas cooler, etc.). This may reduce the amount of refrigerant to be compressed by the main compressor of the refrigeration system, and may thus reduce the energy consumption of the main compressor. This causes the systems of the present disclosure to have increased efficiency, thus using significantly less energy and costing less over time to the end-user compared to conventional solutions. Moreover, where electricity is generated by burning fossil fuels, the systems of the present disclosure may reduce the carbon footprint of datacenter cooling systems. Additionally, the systems of the present disclosure reduce wear on components (e.g., pumps, compressors) compared to conventional systems because the pumps or compressors of the systems disclosed herein are allowed to run more efficiently compared to conventional systems (e.g., the PX performs a portion of the increasing of pressure of the fluid to decrease the load of the pumps and/or compressors). Additionally, some systems described herein reduce the number of moving components (e.g., some systems use auxiliary coolers, receivers, etc. in lieu of booster or compressors, etc.). This also allows systems of the present disclosure to have increased reliability, less maintenance, increased service life of components, decreased downtime of the system, and increased yield (e.g., of refrigeration, cooling, heating, etc.). The systems of the present disclosure may use a pressure exchanger that allows for longer life of components of the system, that increases system efficiency, allows end users to select from a larger range of pumps and/or compressors, reduces maintenance and downtime to service pumps and/or compressors, and allows for new instrumentation and control devices.

Although some embodiments of the present disclosure are described in relation to pressure exchangers, energy recovery devices, and hydraulic energy transfer systems, the current disclosure can be applied to other systems and devices (e.g., pressure exchanger that is not isobaric, rotating components that are not a pressure exchanger, a pressure exchanger that is not rotary, systems that do not include pressure exchangers, etc.).

Although some embodiments of the present disclosure are described in relation to exchanging pressure between fluid used in datacenter cooling systems, datacenter cooling systems, fracing systems, desalinization systems, heat pump systems, and/or refrigeration systems, the present disclosure can be applied to other types of systems. Fluids can refer to liquid, gas, transcritical fluid, supercritical fluid, subcritical fluid, and/or combinations thereof.

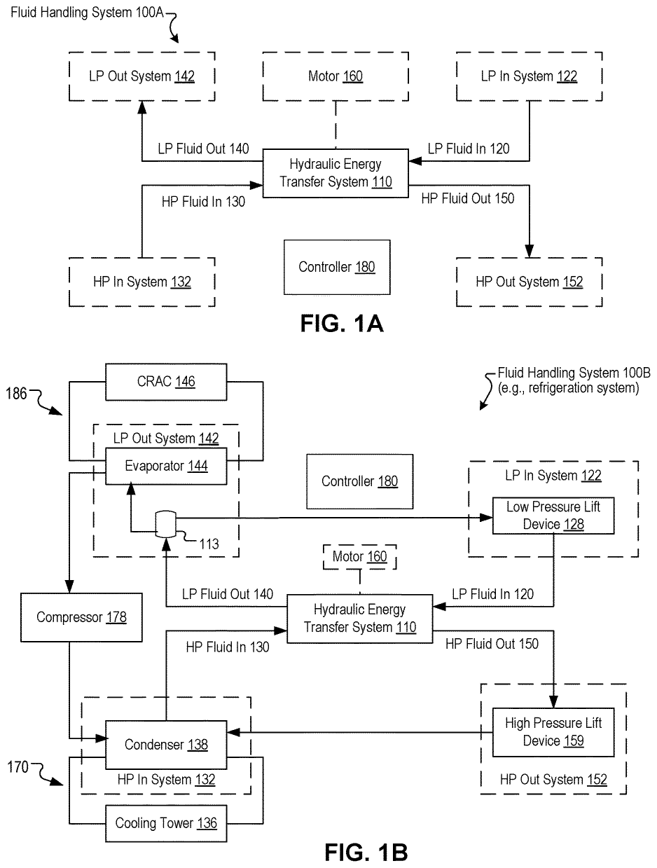

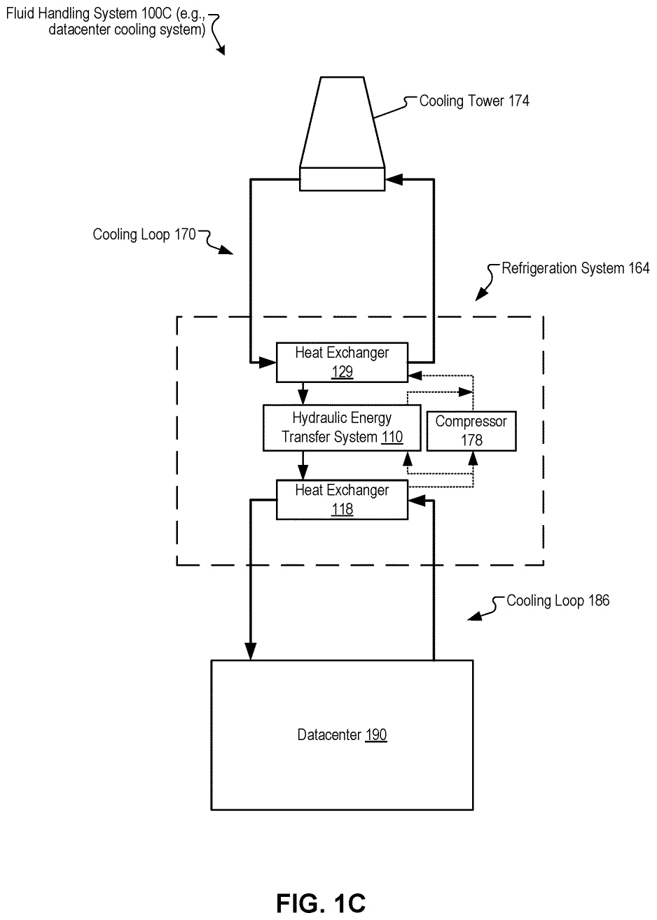

FIG. 1A illustrates a schematic diagram of a fluid handling system 100A that includes a hydraulic energy transfer system 110, according to certain embodiments.

In some embodiments, a hydraulic energy transfer system 110 includes a pressure exchanger (e.g., PX). The hydraulic energy transfer system 110 (e.g., PX) receives low pressure (LP) fluid in 120 (e.g., via a low-pressure inlet) from an LP in system 122. The hydraulic energy transfer system 110 also receives high pressure (HP) fluid in 130 (e.g., via a high-pressure inlet) from HP in system 132. In some embodiments, the HP in system 132 exchanges heat with a cooling tower or chiller unit to reject heat to an ambient environment (e.g., a heat sink). The hydraulic energy transfer system 110 (e.g., PX) exchanges pressure between the HP fluid in 130 and the LP fluid in 120 to provide LP fluid out 140 (e.g., via low-pressure outlet) to LP fluid out system 142 and to provide HP fluid out 150 (e.g., via high-pressure outlet) to HP fluid out system 152. A controller 180 may cause an adjustment of flowrates of HP fluid in 130 and LP fluid out 140 by one or more flow valves, pumps, and/or compressors (not illustrated). The controller 180 may cause flow valves to actuate.

In some embodiments, the hydraulic energy transfer system 110 includes a PX to exchange pressure between the HP fluid in 130 and the LP fluid in 120. In some embodiments, the PX is substantially or partially isobaric (e.g., an isobaric pressure exchanger (IPX)). The PX may be a device that transfers fluid pressure between HP fluid in 130 and LP fluid in 120 at efficiencies (e.g., pressure transfer efficiencies, substantially isobaric) in excess of approximately 50%, 60%, 70%, 80%, 90%, or greater (e.g., without utilizing centrifugal technology). High pressure (e.g., HP fluid in 130, HP fluid out 150) refers to pressures greater than the low pressure (e.g., LP fluid in 120, LP fluid out 140). LP fluid in 120 of the PX may be pressurized and exit the PX at high pressure (e.g., HP fluid out 150, at a pressure greater than that of LP fluid in 120), and HP fluid in 130 may be at least partially depressurized and exit the PX at low pressure (e.g., LP fluid out 140, at a pressure less than that of the HP fluid in 130).

The PX may operate with the HP fluid in 130 directly pressurizing the LP fluid in 120, with or without a fluid separator between the fluids. Examples of fluid separators that may be used with the PX include, but are not limited to, pistons, bladders, diaphragms, and/or the like. In some embodiments, PXs may be rotary devices. Rotary PXs, such as those manufactured by Energy Recovery, Inc. of San Leandro, Calif., may not have any separate valves, since the effective valving action is accomplished internal to the device via the relative motion of a rotor with respect to end covers. In some embodiments, rotary PXs operate with internal pistons to isolate fluids and transfer pressure with relatively little mixing of the inlet fluid streams. In some embodiments, rotary PXs operate without internal pistons between the fluids. Reciprocating PXs may include a piston moving back and forth in a cylinder for transferring pressure between the fluid streams. Any PX or multiple PXs may be used in the present disclosure, such as, but not limited to, rotary PXs, reciprocating PXs, or any combination thereof. In addition, the PX may be disposed on a skid separate from the other components of a fluid handling system 100A (e.g., in situations in which the PX is added to an existing fluid handling system). In some examples, the PX may be fastened to a structure that can be moved from one site to another. The PX may be coupled to a system (e.g., pipes of a system, etc.) that has been built on-site.

In some embodiments, a motor 160 is coupled to hydraulic energy transfer system 110 (e.g., to a PX, to a rotor of a PX, etc.). In some embodiments, the motor 160 controls the speed of a rotor of the hydraulic energy transfer system 110 (e.g., to increase pressure of HP fluid out 150, to decrease pressure of HP fluid out 150, etc.). In some embodiments, motor 160 generates energy (e.g., acts as a generator) based on pressure exchanging in hydraulic energy transfer system 110.

The hydraulic energy transfer system 110 may include a hydraulic turbocharger or hydraulic pressure exchanger, such as a rotating PX. The PX may include one or more chambers and/or channels (e.g., 1 to 100) to facilitate pressure transfer between first and second fluids (e.g., gas, liquid, multi-phase fluid).

In some embodiments, LP in system 122 includes a booster (e.g., a pump and/or a compressor) to increase pressure of fluid to form LP fluid in 120. In some embodiments, LP in system 122 includes an ejector to increase pressure of fluid to form LP fluid in 120. In some embodiments, LP in system 122 receives a gas from LP out system 142. In some embodiments, LP in system 122 receives fluid from a receiver (e.g., a flash tank, etc.). The receiver may receive LP fluid out 140 output from hydraulic energy transfer system 110. In some embodiments, LP out system 142 exchanges heat with a datacenter server room to cool servers.

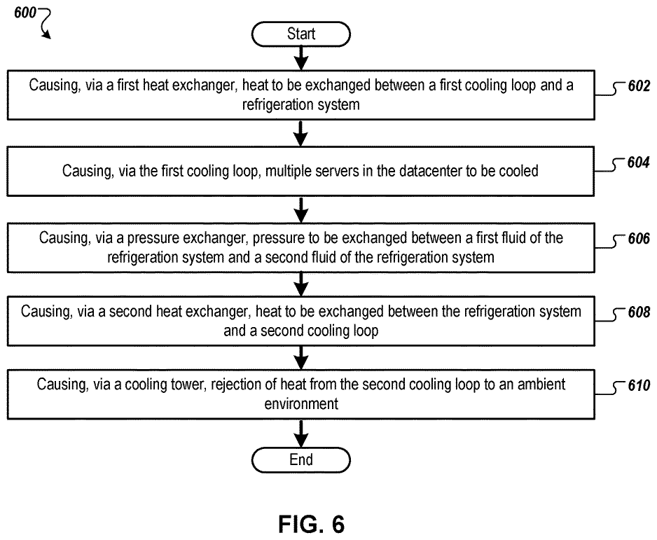

Fluid handling system 100A may additionally include one or more sensors to provide sensor data (e.g., flowrate data, pressure data, velocity data, etc.) associated with the fluids of fluid handling system 100A. Controller 180 may control one or more flow rates of fluid handling system 100A based on the sensor data. In some embodiments, controller 180 causes one or more flow valves to actuate based on sensor data received. In some embodiments, controller 180 can perform the method of FIG. 6.

FIG. 1B illustrates a schematic diagram of a fluid handling system 100B including a hydraulic energy transfer system 110, according to certain embodiments. Fluid handling system 100B may be a refrigeration system such as a datacenter cooling system. In some embodiments, fluid handling system 100B is a thermal energy (e.g., heat) transport system (e.g., heat transport system, thermal transport system). Fluid handling system 100B may be configured to cool an environment (e.g., an indoor space, a refrigerator, a freezer, a datacenter server room, etc.). In some embodiments, fluid handling system 100B includes more components, less components, same routing, different routing, and/or the like than that shown in FIG. 1B. Some of the features in FIG. 1B that have similar reference numbers as those in FIG. 1A may have similar properties, functions, and/or structures as those in FIG. 1A.

Hydraulic energy transfer system 110 (e.g., PX) may receive LP fluid in 120 from LP in system 122 (e.g., low pressure lift device 128, low pressure fluid pump, low pressure booster, low pressure compressor, low pressure ejector, etc.) and HP fluid in 130 from HP in system 132 (e.g., condenser 138, gas cooler, heat exchanger, etc.). The hydraulic energy transfer system 110 (e.g., PX) may exchange pressure between the LP fluid in 120 and HP fluid in 130 to provide HP fluid out 150 to HP out system 152 (e.g., high pressure lift device 159, high pressure fluid pump, high pressure booster, high pressure compressor, high pressure ejector, etc.) and to provide LP fluid out 140 to LP out system 142 (e.g., evaporator 144, heat exchanger, receiver 113, etc.). The LP out system 142 (e.g., evaporator 144, receiver 113) may provide the fluid to compressor 178 and low pressure lift device 128. The evaporator 144 may provide the fluid to compressor 178 and the receiver 113 (e.g., flash tank) may provide fluid to the low pressure lift device 128. The condenser 138 may receive fluid from compressor 178 and high pressure lift device 159. High pressure lift device 159 may be a high pressure booster and low pressure lift device 128 may be a low pressure booster.

In some embodiments, the evaporator 144 receives heat from a computer room air conditioner (CRAC) 146 via a first cooling loop 186. The first cooling loop 186 may carry heat from multiple servers in a server room (e.g., cooled by CRAC 146). Coolant of the first cooling loop 186 may be cooled in evaporator 144 and circulated to CRAC 146. CRAC 146 may use the cooled coolant to cool air in the server room to cool the servers. In some embodiments, a cooling tower 136 receives heat from condenser 138 via a second cooling loop 170. The second cooling loop 170 may carry the heat from the multiple servers in the server room. Coolant of the second cooling loop 170 may be heated in the condenser 138 and circulated to the cooling tower 136. Coolant of the second cooling loop 170 may be cooled in the cooling tower 136. Cooled coolant may be re-circulated form the cooling tower 136 to the condenser 138. Controller 180 may control one or more components of fluid handling system 100B.

The fluid handling system 100B may be a closed system. LP fluid in 120, HP fluid in 130, LP fluid out 140, and HP fluid out 150 may all be a fluid (e.g., refrigerant, the same fluid) that is circulated in the closed system of fluid handling system 100B.

Fluid handling system 100B may additionally include one or more sensors configured to provide sensor data associated with the fluid. One or more flow valves may control flowrates of the fluid based on sensor data received from the one or more sensors. In some embodiments, one or more pressure control valves may be included in system 100B to separate higher pressure fluid from lower pressure fluid. In some embodiments, system 100B may include a flash tank or a receiver to accept a two phase liquid-gas mixture and to separate the mixture into a liquid phase portion and a gas phase portion using difference in densities. The liquid phase portion may be provided to the evaporator after decreasing pressure through valve (e.g., an expansion valve, etc.). The gas phase portion may be provided to the low pressure lift device 128. Excess gas that is not received by the low pressure lift device 128 may be sent to the compressor 178 after decreasing pressure through a valve (e.g., an expansion valve) to the operating pressure of the evaporator 144. In some embodiments, controller 180 causes one or more flow valves (not illustrated) to actuate based on sensor data received.

FIG. 1C illustrates a schematic diagram of a fluid handling system 100C including a hydraulic energy transfer system 110, according to certain embodiments. Fluid handling system 100C may be a cooling system such as a datacenter cooling system. In some embodiments, fluid handling system 100C is a thermal energy (e.g., heat) transport system (e.g., heat transport system, thermal transport system). Fluid handling system 100C may be configured to cool an environment (e.g., an indoor space, a refrigerator, a freezer, a datacenter server room, etc.). In some embodiments, fluid handling system 100C includes more components, less components, same routing, different routing, and/or the like than that shown in FIG. 1C. Some of the features in FIG. 1C that have similar reference numbers as those in FIG. 1A may have similar properties, functions, and/or structures as those in FIGS. 1A and 1B.

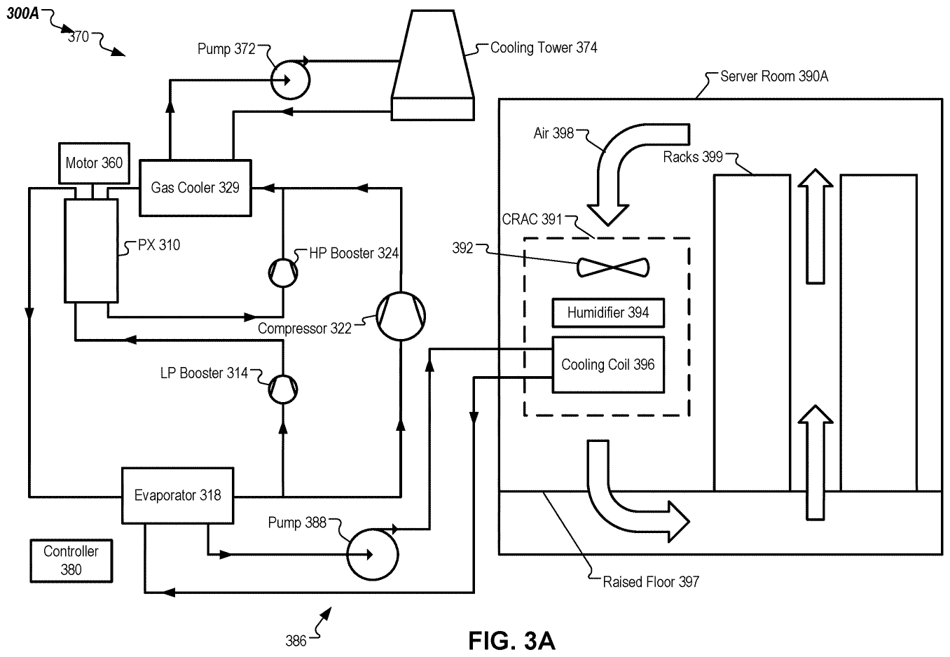

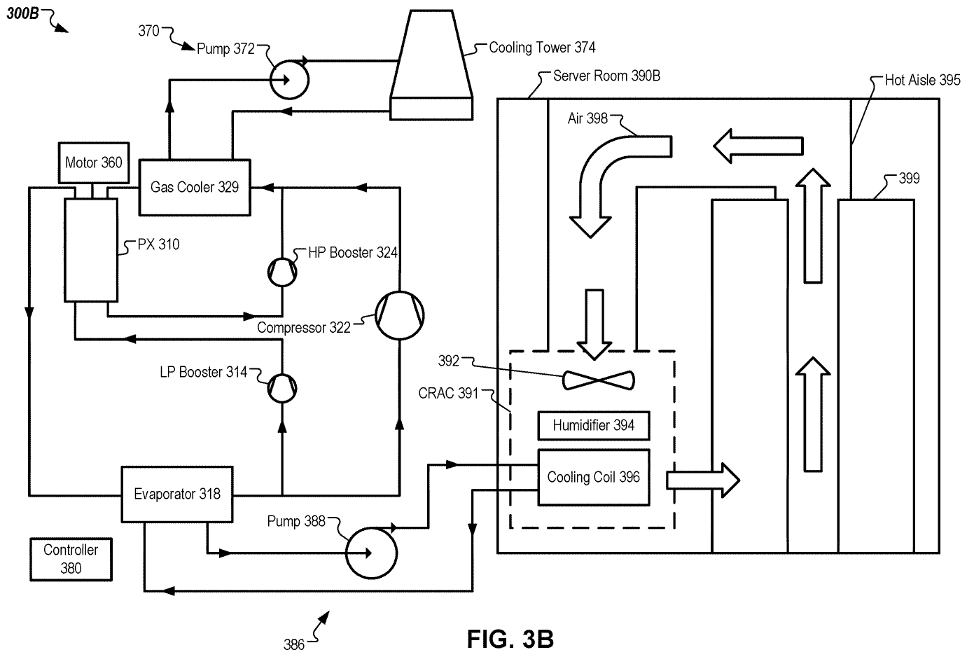

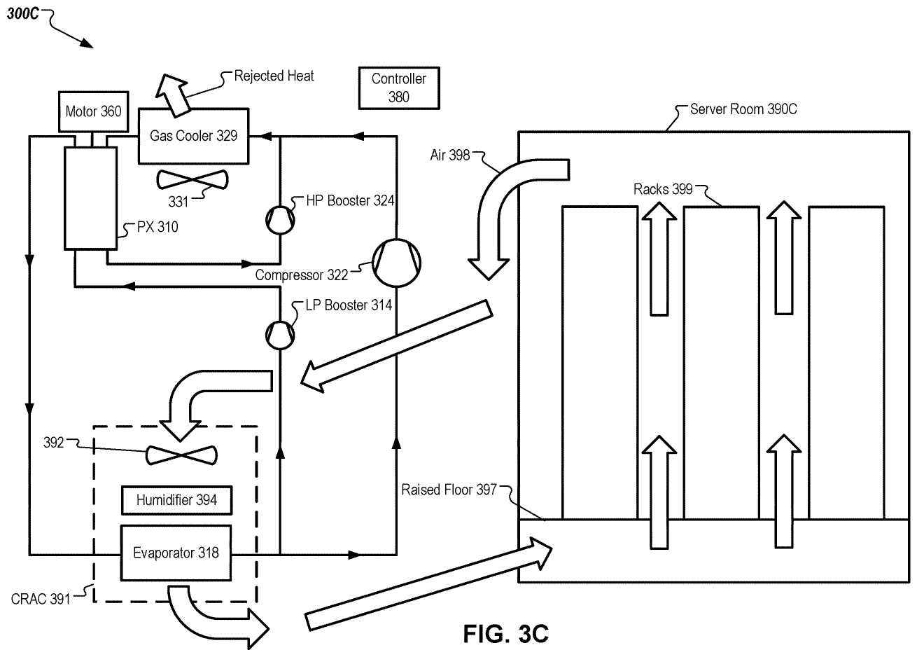

In some embodiments, a refrigeration system 164 is to cool servers of a datacenter 190. Refrigeration system 164 may cool the servers of datacenter 190 by cooling air in the datacenter 190 and/or by cooling liquid coolant. Multiple servers may be disposed in datacenter 190. For example, datacenter 190 may include one or more rooms each containing one or more racks that each support multiple servers. In some embodiments, refrigeration system 164 includes a hydraulic energy transfer system 110 (e.g., a pressure exchanger, etc.) and a compressor 178 as described herein. In some embodiments, refrigeration system 164 includes a first heat exchanger 118 and a second heat exchanger 129. Heat exchanger 118 may exchange heat between the fluid (e.g., at least a portion of the fluid) output from the hydraulic energy transfer system 110 and fluid of a first cooling loop 186. Cooling loop 186 may provide cooled coolant for cooling servers in datacenter 190. Heat from the servers may be transferred by the cooling loop 186 to the heat exchanger 118. In some embodiments, heated refrigeration fluid flows from the first heat exchanger 118 to the second heat exchanger 129. Streams of the refrigeration fluid may be provided to or from the hydraulic energy transfer system 110. In some embodiments, the second heat exchanger 129 exchanges heat between fluid that is to enter the hydraulic energy transfer system 110 and fluid of a second cooling loop 170. Heat may be transferred by the second cooling loop 170 to a cooling tower 174 for cooling the coolant. Cooled coolant may be provided back to the second heat exchanger 129 by the second cooling loop 170. In some embodiments, cooled refrigeration fluid flows from the second heat exchanger 129 to the hydraulic energy transfer system 110. Several possible arrangements of fluid handling system 100C are shown and described herein with respect to FIGS. 3A-3C, 4, and 5A-5F.

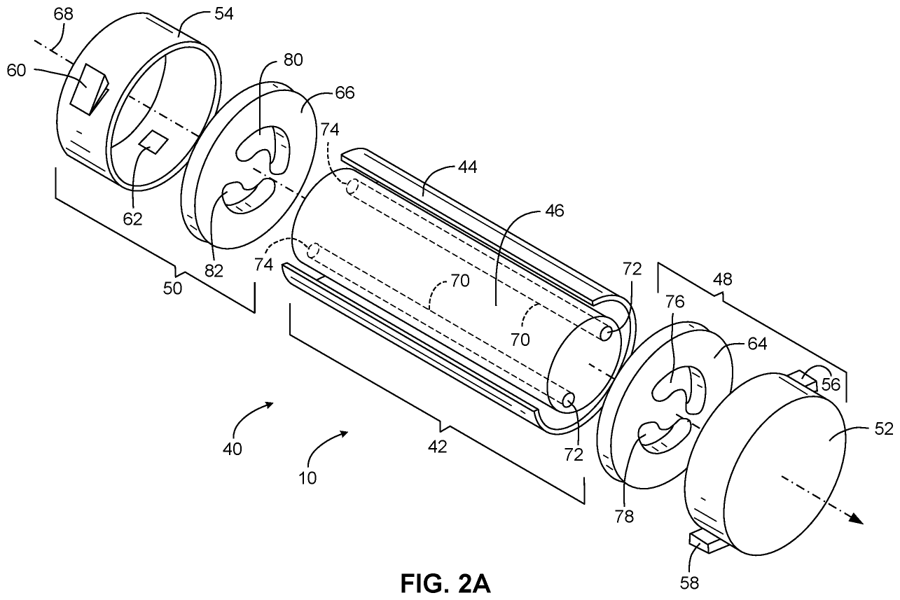

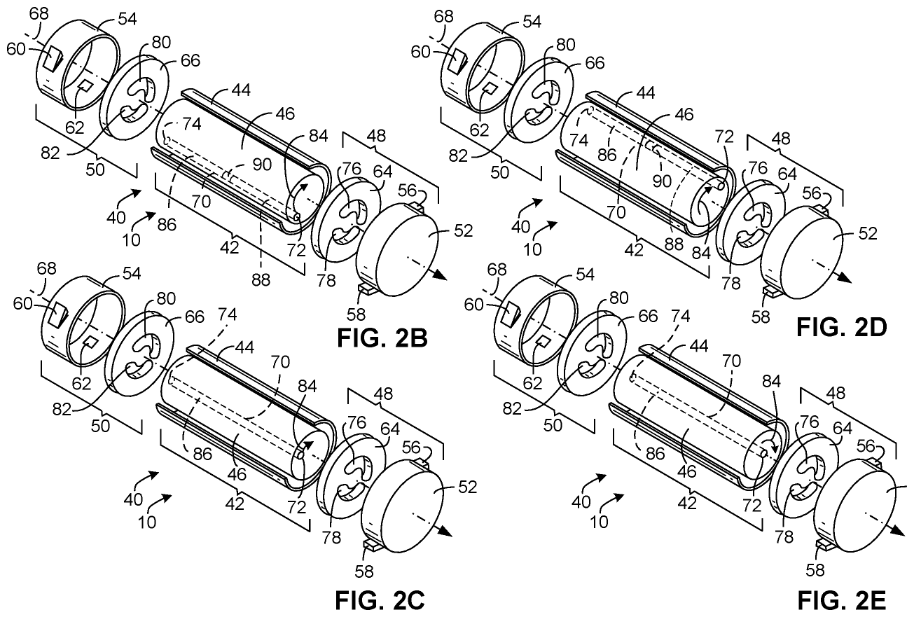

FIGS. 2A-E are exploded perspective views a rotary PX 40 (e.g., rotary pressure exchanger, rotary liquid piston compressor (LPC)), according to certain embodiments. Some of the features in one or more of FIGS. 2A-E may have similar properties, functions, and/or structures as those in one or more of FIGS. 1A-B.

PX 40 is configured to transfer pressure and/or work between a first fluid (e.g., refrigerant, supercritical carbon dioxide, HP fluid in 130) and a second fluid (e.g., refrigerant,, superheated gaseous carbon dioxide, LP fluid in 120) with minimal mixing of the fluids. The rotary PX 40 may include a generally cylindrical body portion 42 that includes a sleeve 44 (e.g., rotor sleeve) and a rotor 46. The rotary PX 40 may also include two end caps 48 and 50 that include manifolds 52 and 54, respectively. Manifold 52 includes respective inlet port 56 and outlet port 58, while manifold 54 includes respective inlet port 60 and outlet port 62. In operation, these inlet ports 56, 60 enable the first and second fluids to enter the rotary PX 40 to exchange pressure, while the outlet ports 58, 62 enable the first and second fluids to then exit the rotary PX 40. In operation, the inlet port 56 may receive a high-pressure first fluid (e.g., HP fluid in 130) output from a condenser, and after exchanging pressure, the outlet port 58 may be used to route a low-pressure first fluid (e.g., LP fluid out 140) out of the rotary PX 40 to a receiver (e.g., flash tank) configured to receive the first fluid from the rotary PX 40. The receiver may form a chamber configured to separate the fluid into a gas and a liquid. Similarly, the inlet port 60 may receive a low-pressure second fluid (e.g., low pressure slurry fluid, LP fluid in 120) from a booster configured to receive a portion of the gas from the receiver and increase pressure of the gas, and the outlet port 62 may be used to route a high-pressure second fluid (e.g., high pressure slurry fluid, HP fluid out 150) out of the rotary PX 40. The end caps 48 and 50 include respective end covers 64 and 66 (e.g., end plates) disposed within respective manifolds 52 and 54 that enable fluid sealing contact with the rotor 46.

One or more components of the PX 40, such as the rotor 46, the end cover 64, and/or the end cover 66, may be constructed from a wear-resistant material (e.g., carbide, cemented carbide, silicon carbide, tungsten carbide, a ceramic such as alumina ceramic, etc.) with a hardness greater than a predetermined threshold (e.g., a Vickers hardness number that is at least 1000, 1250, 1500, 1750, 2000, 2250, or more). In some examples, tungsten carbide may be more durable and may provide improved wear resistance to abrasive fluids as compared to other materials, such as alumina ceramics. Additionally, in some embodiments, one or more components of the PX 40, such as the rotor 46, the end cover 64, the end cover 66, and/or other sealing surfaces of the PX 40, may include an insert. In some embodiments, the inserts may be constructed from one or more wear-resistant materials (e.g., carbide, cemented carbide, silicon carbide, tungsten carbide, etc.) with a hardness greater than a predetermined threshold (e.g., a Vickers hardness number that is at least 1000, 1250, 1500, 1750, 2000, 2250, or more) to provide improved wear resistance.

The rotor 46 may be cylindrical and disposed in the sleeve 44, which enables the rotor 46 to rotate about the axis 68. The rotor 46 may have a plurality of channels 70 (e.g., ducts, rotor ducts) extending substantially longitudinally through the rotor 46 with openings 72 and 74 (e.g., rotor ports) at each end arranged symmetrically about the longitudinal axis 68. The openings 72 and 74 of the rotor 46 are arranged for hydraulic communication with inlet and outlet apertures 76 and 78 (e.g., end cover inlet port and end cover outlet port) and 80 and 82 (e.g., end cover inlet port and end cover outlet port) in the end covers 64 and 66, in such a manner that during rotation the channels 70 are exposed to fluid at high-pressure and fluid at low-pressure. As illustrated, the inlet and outlet apertures 76 and 78 and 80 and 82 may be designed in the form of arcs or segments of a circle (e.g., C-shaped).

In some embodiments, a controller (e.g., controller 180 of FIGS. 1A-B) using sensor data (e.g., revolutions per minute measured through a tachometer or optical encoder, volumetric flow rate measured through flowmeter, etc.) may control the extent of mixing between the first and second fluids in the rotary PX 40, which may be used to improve the operability of the fluid handling system (e.g., fluid handling systems 100A-B of FIGS. 1A-B). In some examples, varying the volumetric flow rates of the first and/or second fluids entering the rotary PX 40 allows the operator (e.g., system operator, plant operator) to control the amount of fluid mixing within the PX 40. In addition, varying the rotational speed of the rotor 46 (e.g., via a motor) also allows the operator to control mixing. Three characteristics of the rotary PX 40 that affect mixing are: (1) the aspect ratio of the rotor channels 70; (2) the duration of exposure between the first and second fluids; and (3) the creation of a barrier (e.g., fluid barrier, piston, interface) between the first and second fluids within the rotor channels 70. First, the rotor channels 70 (e.g., ducts) are generally long and narrow, which stabilizes the flow within the rotary PX 40. In addition, the first and second fluids may move through the channels 70 in a plug flow regime with minimal axial mixing. Second, in certain embodiments, the speed of the rotor 46 reduces contact between the first and second fluids. In some examples, the speed of the rotor 46 (e.g., rotor speed of approximately 1200 revolutions per minute (RPM)) may reduce contact times between the first and second fluids to less than approximately 0.15 seconds, 0.10 seconds, or 0.05 seconds. Third, the rotor channel 70 (e.g., a small portion of the rotor channel 70) is used for the exchange of pressure between the first and second fluids. In some embodiments, a volume of fluid remains in the channel 70 as a barrier between the first and second fluids. All these mechanisms may limit mixing within the rotary PX 40. Moreover, in some embodiments, the rotary PX 40 may be designed to operate with internal pistons or other barriers, either complete or partial, that isolate the first and second fluids while enabling pressure transfer.

FIGS. 2B-2E are exploded views of an embodiment of the rotary PX 40 illustrating the sequence of positions of a single rotor channel 70 in the rotor 46 as the channel 70 rotates through a complete cycle. It is noted that FIGS. 2B-2E are simplifications of the rotary PX 40 showing one rotor channel 70, and the channel 70 is shown as having a circular cross-sectional shape. In other embodiments, the rotary PX 40 may include a plurality of channels 70 with the same or different cross-sectional shapes (e.g., circular, oval, square, rectangular, polygonal, etc.). Thus, FIGS. 2B-2E are simplifications for purposes of illustration, and other embodiments of the rotary PX 40 may have configurations different from those shown in FIGS. 2A-2E. As described in detail below, the rotary PX 40 facilitates pressure exchange between first and second fluids (e.g., a particulate-free fluid and a slurry fluid, higher pressure refrigerant and lower pressure refrigerant, etc.) by enabling the first and second fluids to briefly contact each other within the rotor 46. In some embodiments, the PX facilitates pressure exchange between first and second fluids by enabling the first and second fluids to contact opposing sides of a barrier (e.g., a reciprocating barrier, a piston, not shown). In some embodiments, this exchange happens at speeds that result in limited mixing of the first and second fluids. The speed of the pressure wave traveling through the rotor channel 70 (as soon as the channel is exposed to the aperture 76), the diffusion speeds of the fluids, and/or the rotational speed of rotor 46 may dictate whether any mixing occurs and to what extent.

FIG. 2B is an exploded perspective view of an embodiment of a rotary PX 40 ( ), according to certain embodiments. In FIG. 2B, the channel opening 72 is in a first position. In the first position, the channel opening 72 is in fluid communication with the aperture 78 in end cover 64 and therefore with the manifold 52, while the opposing channel opening 74 is in hydraulic communication with the aperture 82 in end cover 66 and by extension with the manifold 54. The rotor 46 may rotate in the clockwise direction indicated by arrow 84. In operation, low-pressure second fluid 86 (e.g., low pressure slurry fluid) passes through end cover 66 and enters the channel 70, where it contacts the first fluid 88 at a dynamic fluid interface 90. The second fluid 86 then drives the first fluid 88 out of the channel 70, through end cover 64, and out of the rotary PX 40. However, because of the short duration of contact, there is minimal mixing between the second fluid 86 (e.g., slurry fluid) and the first fluid 88 (e.g., particulate-free fluid). In some embodiments, low pressure second fluid 86 contacts a first side of a barrier (e.g., a piston, not shown) disposed in channel 70 that is in contact (e.g., on an opposing side of the barrier) by first fluid 88. The second fluid 86 drives the barrier which pushes first fluid 88 out of the channel 70. In such embodiments, there is negligible mixing between the second fluid 86 and the first fluid 88.

FIG. 2C is an exploded perspective view of an embodiment of a rotary PX 40, according to certain embodiments. In FIG. 2C, the channel 70 has rotated clockwise through an arc of approximately 90 degrees. In this position, the opening 74 (e.g., outlet) is no longer in fluid communication with the apertures 80 and 82 of end cover 66, and the opening 72 is no longer in fluid communication with the apertures 76 and 78 of end cover 64. Accordingly, the low-pressure second fluid 86 is temporarily contained within the channel 70.

FIG. 2D is an exploded perspective view of an embodiment of a rotary PX 40, according to certain embodiments. In FIG. 2D, the channel 70 has rotated through a first prescribed angle of arc (e.g., approximately 60 degrees of arc) from the position shown in FIG. 2B. The opening 74 is now in fluid communication with aperture 80 in end cover 66, and the opening 72 of the channel 70 is now in fluid communication with aperture 76 of the end cover 64. In this position, high-pressure first fluid 88 enters and pressurizes the low-pressure second fluid 86, driving the second fluid 86 out of the rotor channel 70 and through the aperture 80.

FIG. 2E is an exploded perspective view of an embodiment of a rotary PX 40, according to certain embodiments. In FIG. 2E, the channel 70 has rotated through a second prescribed angle or arc (e.g., approximately 270 degrees of arc) from the position shown in FIG. 2B. In this position, the opening 74 is no longer in fluid communication with the apertures 80 and 82 of end cover 66, and the opening 72 is no longer in fluid communication with the apertures 76 and 78 of end cover 64. Accordingly, the first fluid 88 is no longer pressurized and is temporarily contained within the channel 70 until the rotor 46 rotates another 90 degrees, starting the cycle over again.

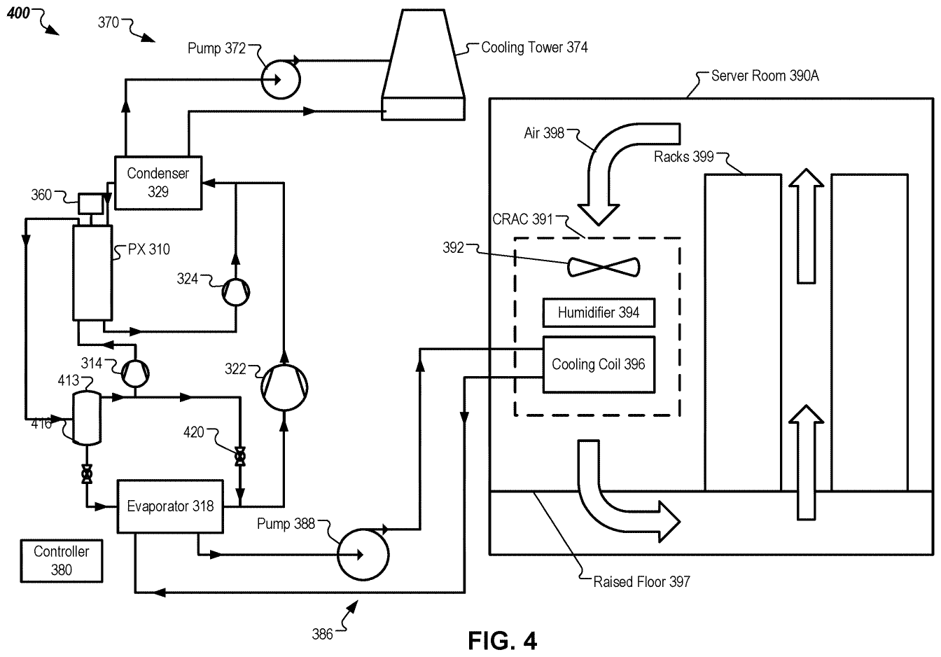

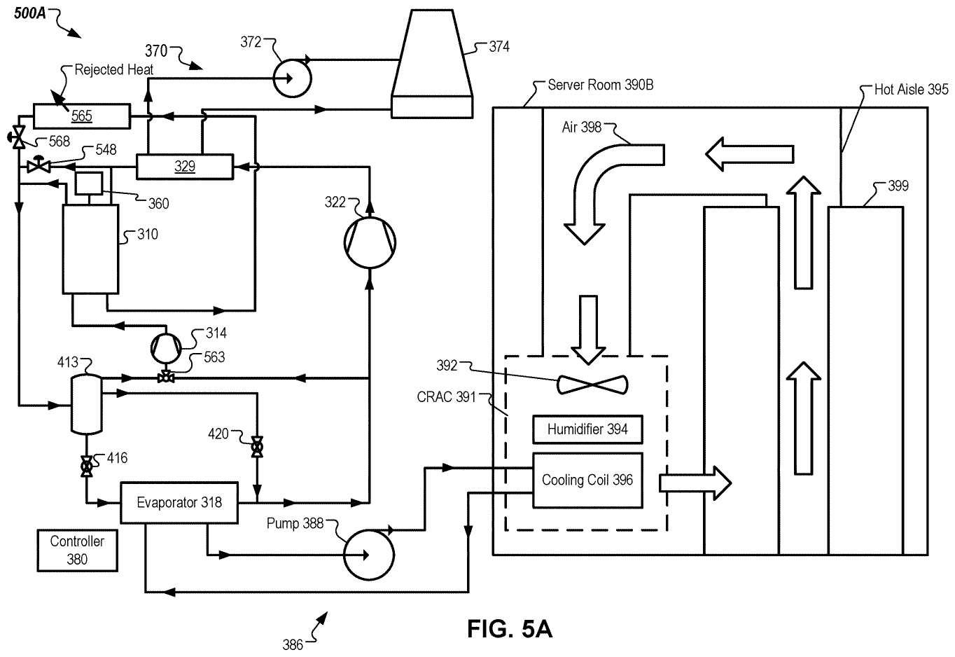

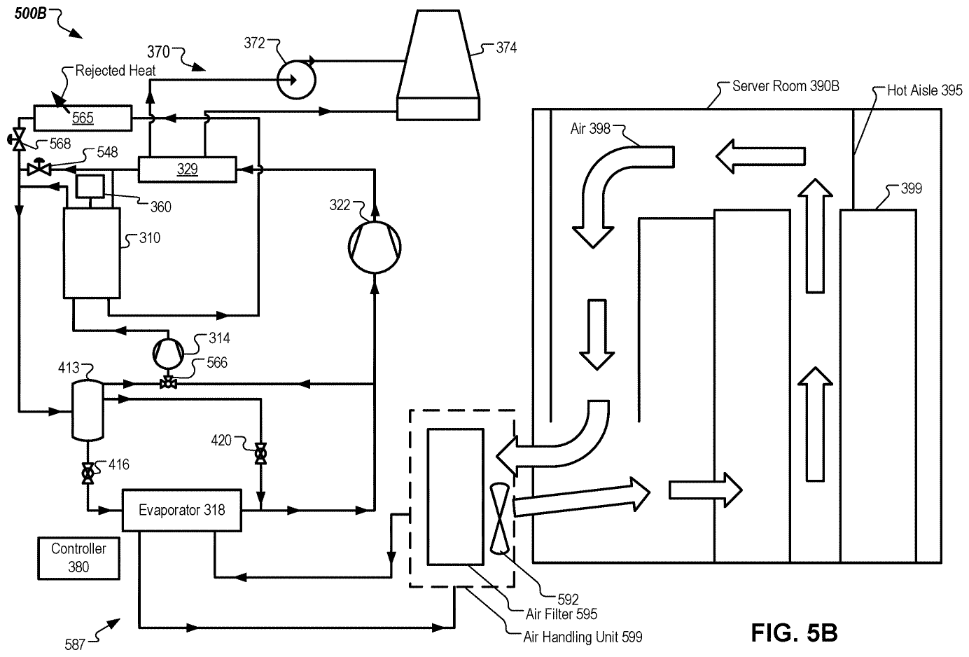

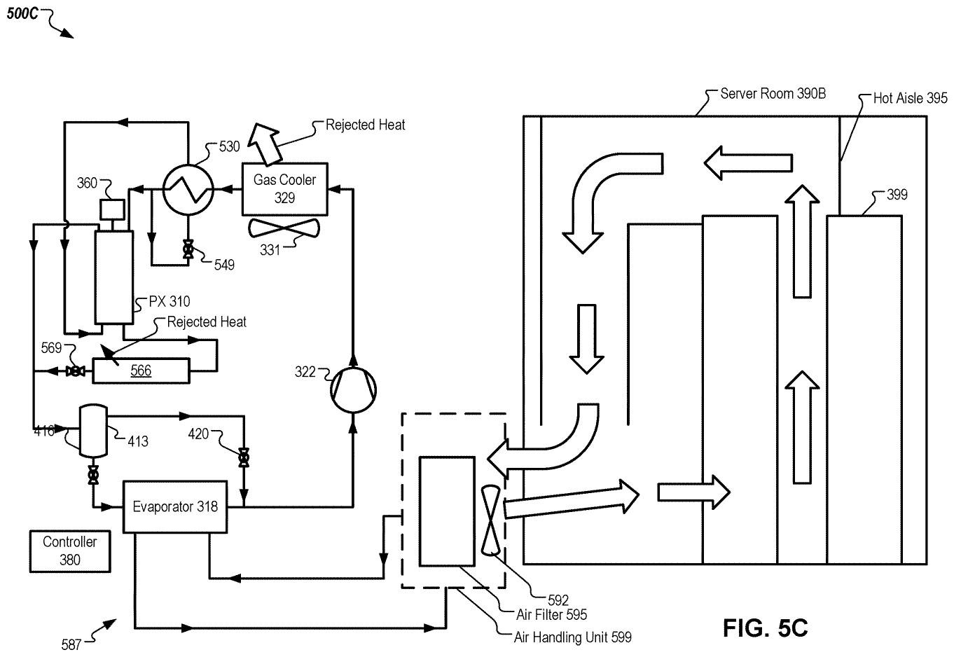

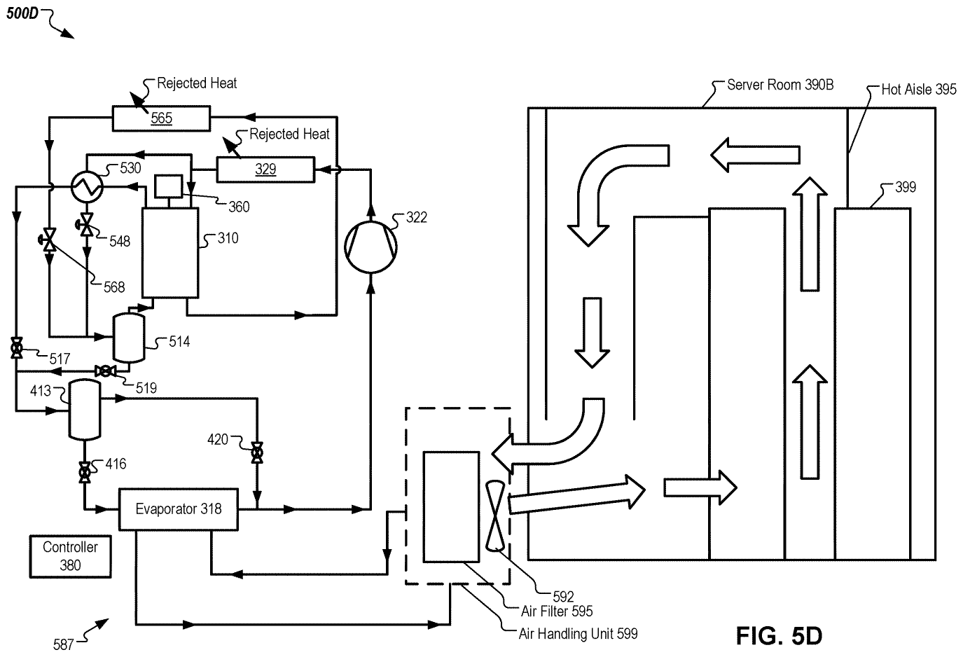

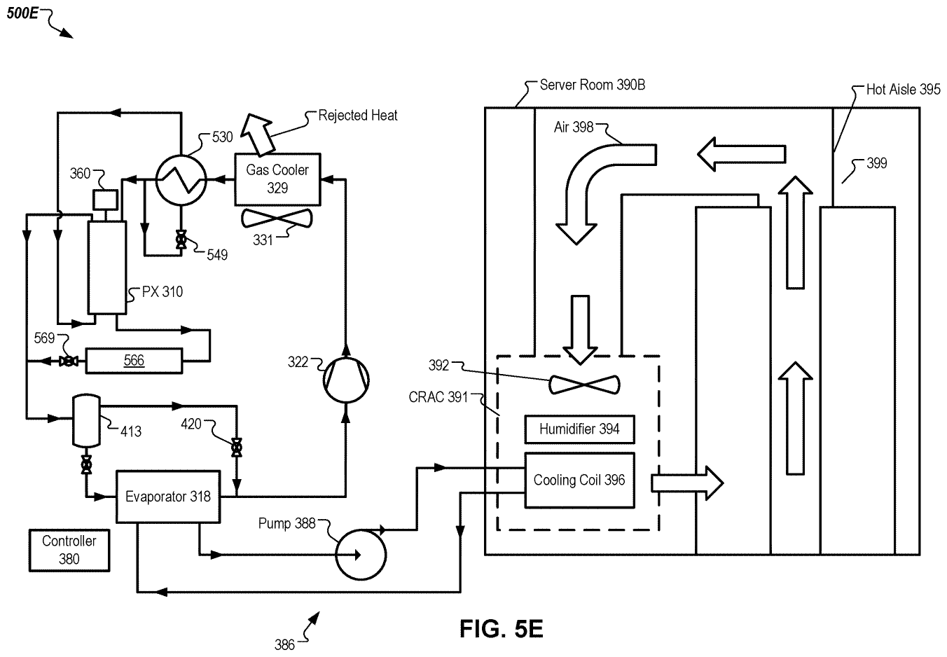

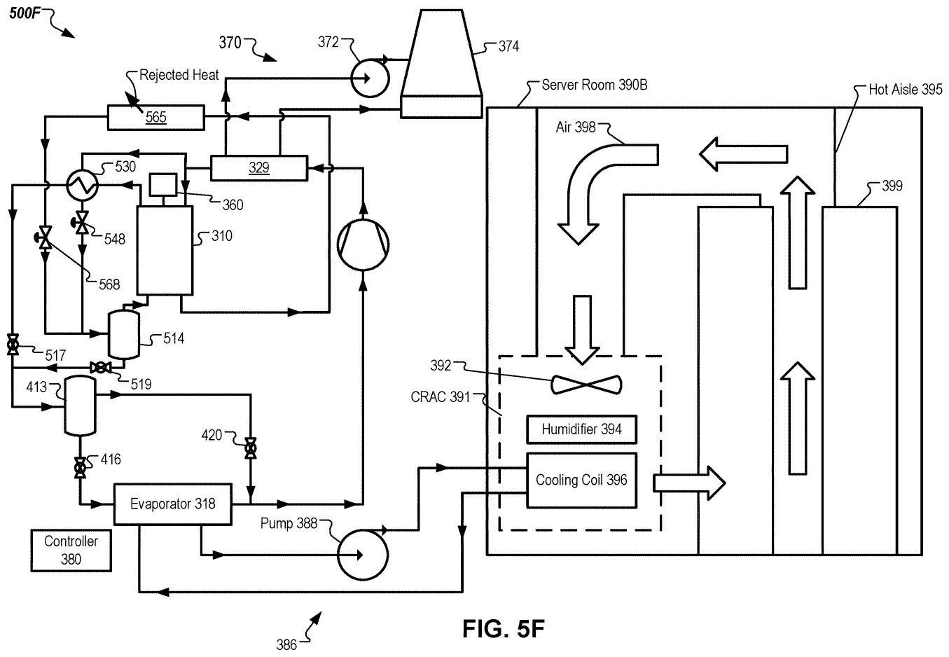

FIGS. 3A-C are schematic diagrams of datacenter cooling systems 300A-C that include pressure exchangers, according to certain embodiments. Some of the features in one or more of FIGS. 3A-C may have similar properties, functions, and/or structures as those in one or more of FIGS. 1A-B and/or one or more of FIGS. 2A-E. Systems of one or more of FIGS. 3A-C, and/or FIGS. 4-5 may be used to perform the method of FIG. 6.

FIG. 3A is a schematic diagram of a datacenter cooling system 300A including a PX 310, according to certain embodiments. In some embodiments, datacenter cooling system 300A is a thermal energy transport system and/or a fluid handling system. PX 310 may be a rotary pressure exchanger. In some embodiments, PX 310 is an isobaric or substantially isobaric pressure exchanger. PX 310 may be configured to exchange pressure between a first fluid and a second fluid. In some embodiments, PX 310 is coupled to a motor 360 (e.g., rotation of a rotor of PX 310 is controlled by the motor 360). In some embodiments, the motor 360 controls the rotational speed of the PX 310. Mass flow (e.g., of the first fluid and/or of the second fluid) through the PX 310 may be related to the rotational speed of the PX 310. In some embodiments, the pressure of the fluid (e.g., the first fluid) in the gas cooler 329 may be related to the rotational speed of the PX 310. In some embodiments, a controller (e.g., controller 380) receives sensor data from one or more sensors of motor 360.

In some embodiments, PX 310 is to receive the first fluid at a high pressure (e.g., HP fluid in 130 of FIGS. 1A-B) via a high pressure inlet. In some embodiments, PX 310 is to receive the second fluid at a low pressure (e.g., LP fluid in 120 of FIGS. 1A-B) via a low pressure inlet. Although there is a reference to “high pressure” and “low pressure,” “high pressure” and “low pressure” may be relative to one another and may not connote certain pressure values (e.g., the pressure of the HP fluid in 130 is higher than the pressure of LP fluid in 120). PX 310 may exchange pressure between the first fluid and the second fluid. PX 310 may provide the first fluid via a low pressure outlet (e.g., LP fluid out 140) and may provide the second fluid via a high pressure outlet (e.g., HP fluid out 150). In some embodiments, the first fluid provided via the low pressure outlet is at a low pressure and the second fluid provided via the high pressure outlet is at a high pressure.

In some embodiments, PX 310 is a rotary PX having a plurality of ducts. In some embodiments, low pressure gaseous refrigerant (e.g., second fluid at a second pressure) enters a duct and is sealed in the duct as duct rotates past a low pressure inlet port. As the duct is exposed to a high pressure outlet port, a pressure wave is generated that compresses the low pressure gaseous refrigerant to high pressure. The low pressure gaseous refrigerant may increase in temperature as it is compressed. Therefore, the low pressure gaseous refrigerant may be converted to high pressure, high temperature refrigerant (e.g., in a supercritical state, etc.). The high pressure, high temperature (e.g., supercritical) refrigerant (e.g., second fluid at a fourth pressure) may be ejected out of the duct through the high pressure outlet port as high pressure, medium temperature supercritical refrigerant (e.g., first fluid at a first pressure) enters the opposite end of the duct (e.g., from the high pressure inlet port). The high pressure, medium temperature supercritical refrigerant may push the now compressed plug of fluid out of the high pressure outlet port. The high pressure, medium temperature fluid plug may then be sealed in the duct as the duct continues its rotation past the high pressure inlet port. As the duct becomes exposed to the low pressure outlet port, an expansion wave propagates through the duct and converts the high pressure, medium temperature supercritical refrigerant into a low pressure, low temperature two-phase liquid gas mixture (e.g., first fluid at a third pressure) which may then ejected out of the duct through a low pressure outlet port.

In some embodiments, fluid handling system 300A includes a gas cooler 329 (e.g., a condenser, etc.), an evaporator 318, and a compressor 322. In some embodiments, the gas cooler 329 is a heat exchanger that provides the heat from the refrigerant (e.g., the first fluid) to a cooling loop (e.g., a second cooling loop 370). The gas cooler 329 may remove the heat from the refrigerant and provide the heat to a cooling loop. In some embodiments, gas cooler 329 is a heat exchanger that cools fluid flowing through the gas cooler 329 (e.g., cools a refrigerant in a gas state, etc.). In some embodiments, gas cooler 329 is a heat exchanger that condenses fluid flowing through the gas cooler 329 (e.g., while cooling the flowing fluid) from a gas state to a liquid state. In some embodiments, the pressure of the fluid within the gas cooler 329 is above the critical pressure of the fluid. The gas cooler 329 may provide the heat from the fluid (e.g., gas) to second cooling loop 370. In some embodiments, the temperature of the fluid in the gas cooler 329 may be lowered, but the fluid may not condense (e.g., the fluid does not change phase from gas to liquid). In some embodiments, above the critical pressure of the fluid (e.g., of the refrigerant), the thermodynamic distinction between liquid and gas phases of the fluid within the gas cooler 329 disappears and there is only a single state of fluid called the supercritical state.

In some examples, evaporator 318 may provide heat received by system 300A from a first cooling loop 386 to a refrigeration fluid. In some embodiments, the refrigeration fluid is CO₂ or another refrigeration fluid. The heat may be rejected to a second cooling loop 370 via the gas cooler 329. In some embodiments, the heat received by system 300A is excess heat from multiple servers (e.g., computing units, server components, etc.) disposed in server room 390A. Details regarding the cooling of the multiple servers in server room 390A is discussed below.

Compressor 322 may increase corresponding pressure of the refrigeration fluid along a flow path between the evaporator 318 and the gas cooler 329. The refrigeration fluid may flow substantially in a cycle (e.g., from gas cooler 329 to PX 310 to evaporator 318 to compressor 322 to gas cooler 329, etc.). All fluid flowing into compressor 322 may be in a gas state (e.g., a superheated gas state) so that no liquid may enter the compressor 322. Preventing liquid from entering compressor 322 may minimize damage to the compressor 322 (e.g., because of incompressible liquid).

In some embodiments, fluid handling system 300A includes a low-pressure booster (e.g., LP booster 314) and/or a high-pressure booster (e.g., HP booster 324). Both LP booster 314 and HP booster 324 may be configured to increase (e.g., “boost”) pressure of the second fluid. For instance, LP booster 314 may increase pressure of the second fluid output from evaporator 318 (e.g., received from the PX 310). HP booster 324 may increase pressure of the second fluid output by the PX 310. The second fluid may be provided (e.g., by HP booster 324) to combine with fluid output from the compressor 322 (e.g., upstream of an inlet of the gas cooler 329) to be provided to the gas cooler 329. LP booster 314 may increase pressure less than a threshold amount (e.g., LP booster 314 may operate over a pressure differential that is less than a threshold amount). In some examples, LP booster 314 may increase pressure of the second fluid approximately 10 to 60 psi. The second fluid may experience pressure loss (e.g., due to fluid friction loss in piping) as the second fluid flows from the LP booster 314 to the second inlet of the PX 310. HP booster 324 may increase pressure of the second fluid between the second outlet of the PX 310 and an inlet of the gas cooler 329. HP booster 324 may increase pressure less than a threshold amount (e.g., HP booster 324 may operate over a pressure differential that is less than a threshold amount). In some examples, HP booster 324 may increase pressure of the second fluid approximately 10 to 60 psi. HP booster 324 may increase pressure of the second fluid to a pressure that substantially matches the pressure of fluid output from the compressor 322 (e.g., the pressure of gas cooler 329). In contrast to LP booster 314 and HP booster 324, the compressor 322 increases pressure of fluid more than a threshold amount (e.g., compressor 322 may operate over a pressure differential that is greater than a threshold amount). In some examples, the compressor 322 may increase pressure of the fluid greater than approximately 200 psi. In some embodiments, controller 380 controls a flowrate of fluid through the PX 310 by controlling a flowrate of LP booster 314. In some examples, controller 380 may set a flowrate of LP booster 314 to control a flowrate of first fluid through the PX 310.

In some embodiments, evaporator 318 is a heat exchanger to exchange (e.g., provide) corresponding thermal energy from first cooling loop 386 to a refrigeration fluid. The refrigeration fluid may transition from a liquid state to a vapor state (e.g., a gas state, etc.) in the evaporator 318. In some examples, evaporator 318 may receive heat (e.g., thermal energy) from coolant (e.g., heat transfer fluid, water, a water-glycol mixture, etc.) of the first cooling loop and provide the heat to the refrigeration fluid. In some embodiments, the heat is excess heat from servers disposed in racks 399 in server room 390A. In some embodiments, air circulating inside server room 390A is used to cool servers (e.g., server components, etc.). In some embodiments, circulating air 398 carries heat away from the servers and is directed into CRAC 391. CRAC 391 may be a cooler unit to cool air 398. A fan 392 may blow air 398 through/past an optional humidifier 394. Humidifier 394 may add moisture to air 398. In some embodiments, fan 392 blows air through cooling coil 396. In some embodiments, cooling coil 396 is a heat exchanger (e.g., such as a brazed plate heat exchanger, a shell-and-tube heat exchanger, etc.) configured to exchange heat between air 398 and coolant of first cooling loop 386. In some embodiments, heat from air 398 is provided to the coolant of the first cooling loop 386 via the cooling coil 396. In some embodiments, a pump 388 is configured to pump coolant along a flow path of the first cooling loop 386 between the cooling coil 396 and the evaporator 318. Heat from the servers may be provided to evaporator 318 by the first cooling loop 386. In some embodiments, air 398 is cooled by the coolant via the cooling coil 396. In some embodiments, the cooled air 398 is routed from CRAC 391 to a space underneath raised floor 397 (e.g., via ducting, etc.). The cooled air 398 then flows up through perforations in the raised floor 397 and amongst the servers in racks 399 to cool the servers. Warm air 398 is then routed to the CRAC 391. In some embodiments, raised floor 397 is configured to support multiple server racks 399, each server rack supporting multiple servers.

In some embodiments, the gas cooler 329 is a heat exchanger to transfer corresponding thermal energy (e.g., heat) between refrigeration fluid and the second cooling loop 370. In some embodiments, the gas cooler 329 is to provide thermal energy from the refrigeration fluid to coolant (e.g., heat transfer fluid, water, a water-glycol mixture, etc.) of the second cooling loop 370. In some embodiments, the heat transferred to the second cooling loop 370 by the gas cooler 329 corresponds to the heat transferred from the first cooling loop 386 in the evaporator 318 (e.g., the heat from servers in server room 390A). In some embodiments, a pump 372 circulates coolant along a flow path of the second cooling loop 370 between the gas cooler 329 and a cooling tower 374. The cooling tower 374 may be a cooling tower or a chiller unit. In some embodiments, the cooling tower 374 receives warm coolant and cools the coolant by rejecting the heat from the coolant to an ambient environment. The ambient environment may be a cold sink for the rejection of heat. Cooled coolant may flow from the cooling tower 374 to the gas cooler 329.

In some embodiments, the temperature and/or humidity of the ambient environment affects the performance of the cooling tower 374. The performance of the cooling tower 374 may affect the performance of system 300A. For example, cooling tower 374 may be able to cool the coolant of the second cooling loop 370 to a temperature dictated by the relative humidity and/or temperature of the ambient environment. The refrigerant flowing through gas cooler 329 may be cooled no cooler than the temperature of the coolant of second coolant loop 370. Cooling the refrigerant to a cooler temperature in the gas cooler 329 provides more efficient cooling of the coolant of the first cooling loop 386 in the evaporator 318. When the temperature of refrigerant exiting the gas cooler 329 is lower, the refrigerant after expanding through the PX 310 is closer to a saturated liquid state, meaning the refrigerant contains more liquid in a saturated mixture. The liquid refrigerant provides increased cooling capacity when flowed through the evaporator 318 compared to gaseous refrigerant. Thus, decreasing the temperature of the coolant of the second cooling loop 370 (e.g., cooled by the cooling tower 374) allows more heat absorption in evaporator 318 (e.g., by the refrigerant), leading to increased efficiency of system 300A.

System 300A may include a controller 380 (e.g., controller 180 of FIGS. 1A-D). Controller 380 may control the boosters and/or compressors of system 300A. Controller 380 may receive sensor data from one or more sensors of system 300A. The sensors may include pressure sensors, flowrate sensors, and/or temperature sensors. In some embodiments, controller 380 controls a motor coupled to PX 310 (e.g., motor 360). In some embodiments, controller 380 receives motor data from one or more motor sensors associated with the motor 360. Motor data received from motor sensors may include current motor speed (e.g., revolutions per minute), total motor run time, motor run time between maintenance operations, and/or total motor revolutions. Motor data may be indicative of a performance state of the motor.

In some embodiments, controller 380 receives sensor data indicative of a temperature of coolant of first cooling loop 386 and/or a temperature of air 398 in server room 390A. Controller 380 may control LP booster 314, HP booster 324, and/or compressor 322 based on sensor data received from one or more sensors of the system 300A (e.g., one or more fluid flowrate sensors, temperature sensors, pressure sensors, etc.). In some embodiments, one or more sensors (e.g., pressure sensors, flow sensors, temperature sensors, etc.) are disposed proximate inlets and/or outlets of the various components of the system 300A. In some embodiments, one or more sensors are disposed internal to the components of the system 300A. In some examples, a pressure sensor may be disposed proximate the inlet of the compressor 322 and an additional pressure sensor may be disposed proximate the outlet of the compressor 322. In some examples, a temperature sensor may be disposed proximate the inlet of the evaporator 318 and another temperature sensor may be disposed proximate the outlet of the evaporator 318. In some examples, a temperature sensor may be disposed internal to the gas cooler 329. In some examples, a flow sensor may be located at each of the inlets and outlets of the PX 310 to measure a flow of the first fluid and the second fluid into and out of the PX 310.

Described herein are references to “first fluid” and “second fluid.” In some embodiments, the first fluid and the second fluid are the same type of fluid (e.g., are a refrigeration fluid flowing in a fluid handling system). “First fluid” may refer to fluid flowing through the PX 310 from the high pressure inlet to the low pressure outlet of the PX 310 and/or fluid flowing to or from the high pressure inlet and/or the low pressure outlet of the PX 310. “Second fluid” may refer to fluid flowing through the PX 310 from the low pressure inlet to the high pressure outlet of the PX 310 and/or fluid flowing to or from the low pressure inlet and/or the high pressure outlet of the PX 310. In some embodiments, the first fluid may be a refrigerant fluid in a supercritical state (e.g., supercritical CO₂). In some embodiments, the first fluid may be a refrigerant fluid in a liquid state (e.g., liquid CO₂). In some embodiments, the second fluid may be a refrigerant fluid in a gaseous state (e.g., CO₂ vapor). In some embodiments, the second fluid may be a refrigerant fluid in a two-phase state (e.g., a liquid-gas mixture of CO₂). In some embodiments, the second fluid may be a refrigerant fluid in a liquid state (e.g., liquid CO₂).

FIG. 3B is a schematic diagram of a datacenter cooling system 300B including a PX 310, according to certain embodiments. In some embodiments, features that have reference numbers that are similar to reference numbers in other figures include similar properties, structures, and/or functionality as those described in other figures. In some examples, features of system 300B have similar properties, structures, and/or functionality as system 300A of FIG. 3A.

In some embodiments, system 300B provides cooling for servers disposed in server room 390B. In some embodiments, cool air 398 is provided by CRAC 391 to racks 399. The servers may be disposed in racks 399. In some embodiments, the cool air 398 receives heat from the servers (e.g., from the server components) and flows upwards in hot aisle 395. In some embodiments, hot aisle 395 is the space between two racks 399. In some embodiments, hot aisle 395 separates the heated air from the cooled air so that cooling of the servers can take place more efficiently. Hot aisle 395 may direct heated air away from the cooled air and/or away from the servers. In some embodiments, ducting routes the heated air 398 from hot aisle 395 to the intake of CRAC 391 for cooling and/or conditioning (e.g., via the humidifier 394 and/or the cooling coil 396, etc.).

FIG. 3C is a schematic diagram of a datacenter cooling system 300C including a PX 310, according to certain embodiments. In some embodiments, features that have reference numbers that are similar to reference numbers in other figures include similar properties, structures, and/or functionality as those described in other figures. In some examples, features of system 300C have similar properties, structures, and/or functionality as system 300A of FIG. 3A and/or system 300B of FIG. 3B.

In some embodiments, system 300C provides cooling for servers disposed in server room 390C. In some embodiments, warm air 398 from server room 390C is routed (e.g., via ducting, etc.) to CRAC 391. In some embodiments, CRAC 391 includes evaporator 318. In some embodiments, warm air 398 exchanges heat with refrigerant via evaporator 318. In some embodiments, the evaporator 318 is configured to cool air 398 circulating through the server room 390C. Refrigerant flowing through evaporator 318 may be heated and air 398 may be cooled. In some embodiments, the cooled air 398 is routed (e.g., via ducting, etc.) from CRAC 391 to the space beneath the raised floor 397 of the server room 390C. In some embodiments, air 398 flows through perforations in the raised floor 397 upwards through the racks 399 to cool the servers. Warmed air 398 carrying heat away from the servers is routed to the CRAC 391 to provide the heat from the servers to the refrigerant via evaporator 318. In some embodiments, the heat is rejected directly to an ambient environment by the gas cooler 329 (e.g., without use of a cooling loop or a cooling tower). A fan 331 may blow air across the gas cooler 329 (e.g., across fins of the gas cooler 329) to aid in rejecting heat from the refrigerant to the ambient environment. In some embodiments, system 300C may be used where cost savings are a consideration and/or where the datacenter is operating in a cold (e.g., colder) climate such as arctic climates.

FIG. 4 is a schematic diagram of a datacenter cooling system 400 including a PX 310, according to certain embodiments. In some embodiments, features that have reference numbers that are similar to reference numbers in other figures include similar properties, structures, and/or functionality as those described in other figures. In some examples, features of system 400 have similar properties, structures, and/or functionality as system 300A of FIG. 3A. In some embodiments, system 400 can include any of server room 390A, 390B, and/or 390C as illustrated in FIGS. 3A-3C.

In some embodiments, system 400 includes a flash tank 313 (e.g., a receiver, etc.). In some embodiments, flash tank 413 is a receiver configured to receive a flow of fluid (e.g., first fluid) output from the low pressure outlet of the PX 310. Flash tank 413 may form a chamber to collect the first fluid from the first outlet of the PX 310. Flash tank 413 may receive the first fluid in a two-phase state (e.g., liquid and gas). In some embodiments, flash tank 413 is a tank constructed of welded sheet metal. Flash tank 413 may be made of steel (e.g., steel sheet metal, steel plates, etc.). The first fluid (e.g., at a low pressure) may separate into gas and liquid inside the flash tank 413. Liquid may settle at the bottom of the flash tank 413 while gas may rise to the top of the flash tank 413. The liquid may flow from the flash tank 413 towards the evaporator 318 (e.g., via expansion valve 416). The chamber of flash tank 413 may be maintained at a set pressure. The pressure may be set by a user (e.g., an operator, a technician, an engineer, etc.) and/or by a controller (e.g., controller 380). In some embodiments, the pressure of the flash tank 413 is controlled by one or more valves (e.g., flash gas valve 420, a pressure regulator valve, a safety valve, etc.). In some embodiments, the flash tank 413 includes at least one pressure sensor (e.g., pressure transducer).

In some embodiments, system 400 includes an expansion valve 416. In some embodiments, expansion valve 416 is disposed along a flow path between flash tank 413 and evaporator 318. Expansion valve 416 may be an adjustable valve (e.g., an electronic expansion valve, a thermostatic expansion valve, a ball valve, a gate valve, a poppet valve, etc.). Expansion valve 416 may be controllable by a user (e.g., a technician, an operator, an engineer, etc.) or by controller 380. In some embodiments, the expansion valve 416 is caused to actuate by controller 380 based on sensor data (e.g., pressure sensor data, flowrate sensor data, temperature sensor data, etc.). In some embodiments, expansion valve 416 is a thermal expansion valve. Expansion valve 416 may actuate (e.g., open and/or close) based on temperature data associated with the evaporator 318 (e.g., temperature data of the refrigeration fluid exiting the evaporator). In some examples, a sensing bulb (e.g., a temperature sensor, a pressure sensor dependent upon temperature, etc.) of the expansion valve 416 may increase or decrease pressure on a diaphragm of the expansion valve 416, causing a poppet valve coupled to the diaphragm to open or close, thus causing more or less flow of fluid to the evaporator 318, causing more or less expansion of the fluid. The sensing bulb of the expansion valve may be positioned proximate to the downstream end of the evaporator 318 (e.g., proximate the fluid outlet of the evaporator 318) and may be fluidly coupled to the diaphragm via a sensing capillary (e.g., a conduit between the sensing bulb and the expansion valve 416). In some embodiments, expansion valve 416 is controlled and/or actuated entirely based on electronic commands (e.g., from controller 380). In some embodiments, the enthalpy of the refrigerant flowing through the expansion valve 416 is the same on the upstream side of the valve as on the downstream side. Therefore, the enthalpy of the liquid refrigerant exiting the flash tank 413 may be the same as the enthalpy of the refrigerant entering the evaporator 318.

In some embodiments, system 400 includes a flash gas valve 420 to regulate a flow of gas on a flash gas bypass flow path. In some embodiments, flash gas valve 420 is a bypass valve that regulates a flow of gas from a gas outlet of the flash tank 413 to be combined with output of the evaporator 318. In some embodiments, the flow of gas from the flash tank 413 flows along the flash gas bypass flow path to bypass the evaporator 318. In some embodiments, the flash gas flow path is between flash tank 413 and a location downstream of an outlet of the evaporator 318. The gas flowing along the flash gas bypass flow path may be combined with output of the evaporator 318. The flash gas valve 420 may cause gas collected in the flash tank 413 to expand (e.g., decrease in pressure) as the gas flows toward the compressor 322. The flash gas valve 420 may, in some embodiments, be an adjustable valve. In some embodiments, the flash gas valve 420 is caused to actuate by controller 380 based on sensor data.

In some embodiments, LP booster 314 receives a flow of fluid from flash tank 413. In some embodiments, LP booster 314 receives a flow of gas from flash tank 413. In some examples, LP booster 314 receives a portion of the gas flowing along the flash gas bypass flow path between flash tank 413 and the flash gas valve 420. In some embodiments, the LP booster 314 receives the fluid and increases pressure of the fluid to form the second fluid (e.g., at the second pressure). The fluid is provided at the increased pressure (e.g., second pressure) to the second inlet of the PX 310 as the second fluid. In some embodiments, LP booster 314 is a compressor or pump that operates over a low pressure differential to “boost” the pressure of the gas received from flash tank 413. In some embodiments, the HP booster 324 is a compressor or pump that operates over a low pressure differential to “boost” the pressure of the fluid (e.g., second fluid) received from the second outlet of the PX. In some embodiments, a compressor is configured to increase pressure of a fluid substantially made up of gas, while a pump is configured to increase pressure of a fluid substantially made up of liquid.

FIGS. 5A-5F are schematic diagrams of datacenter cooling systems 500A-500F including pressure exchangers, according to certain embodiments. Referring to FIG. 5A, a schematic diagram of a datacenter cooling system 500A including a PX 310 is shown, according to certain embodiments. In some embodiments, features that have reference numbers that are similar to reference numbers in other figures include similar properties, structures, and/or functionality as those described in other figures. In some examples, features of system 500A have similar properties, structures, and/or functionality as systems 300A-300C of FIGS. 3A-3C and system 400 of FIG. 4. In some embodiments, system 500A can include any of server room 390A, 390B, and/or 390C as illustrated in FIGS. 3A-3C.

In some embodiments, system 500A includes a parallel valve 548. Parallel valve 548 may be an expansion valve or a flow control valve. In some embodiments, parallel valve 548 selectively regulates a flow of fluid from the outlet of gas cooler 329 to the flash tank 413 in parallel with the PX 310. In some embodiments parallel valve 548 controls the pressure of the gas cooler 329 (e.g., gas cooler) by selectively opening or closing its orifice (e.g., of the parallel valve 548). In some embodiments, parallel valve 548 can be actuated to selectively regulate the flow of fluid or to selectively regulate the pressure of the fluid within the gas cooler 329. Parallel valve 548 may selectively provide a portion of fluid output by the gas cooler 329 to the expansion tank 413. In some examples, parallel valve 548 can be actuated to be further opened to flow more fluid from the gas cooler 329 to the flash tank 413, or parallel valve 548 can be actuated to be further closed to flow less fluid from the gas cooler 329 to the flash tank 413 The fluid may expand as the fluid flows through the parallel valve 548, causing a decrease in pressure and/or temperature of the fluid. In some embodiments, the controller 380 may cause the parallel valve 548 to actuate (e.g., to open or close) based on sensor data received from one or more sensors.

In some embodiments, system 500A includes an auxiliary gas cooler 565 (e.g., an auxiliary condenser, an auxiliary heat exchanger, etc.), an auxiliary parallel valve 568, and/or an LP selector valve 563. In some embodiments, the auxiliary gas cooler 565 receives the second fluid from the high pressure outlet of the PX 310. The auxiliary gas cooler 565 may be a condenser and/or a gas cooler as described herein. In some embodiments, the auxiliary gas cooler 565 is a heat exchanger that exchanges thermal energy (e.g., heat) between the second fluid and an ambient environment. In some embodiments, the auxiliary gas cooler 565 exchanges thermal energy between the second fluid and the coolant of the second cooling loop 370. In some embodiments, the auxiliary gas cooler 565 operates at a pressure different (e.g. lower) than gas cooler 329 The auxiliary gas cooler 565 operating at a lower pressure than the gas cooler 329 may eliminate the need for a booster (e.g., HP booster 324) to make up this differential pressure because the second fluid output from the PX 310 (e.g., at a high pressure) may be at a lower pressure than the pressure of the gas cooler 329.

In some embodiments, the second fluid flows from the auxiliary gas cooler 565 to the auxiliary parallel valve 568. In some embodiments, the auxiliary parallel valve 568 is substantially similar to the parallel valve 548. In some examples, the auxiliary parallel valve 568 may be a flow control valve to control the flow of the second fluid from the auxiliary gas cooler 565 towards the flash tank 413. In some embodiments, the auxiliary parallel valve 568 is an expansion valve. The second fluid may expand as the second fluid flows through the auxiliary parallel valve 568. In some embodiments, the auxiliary parallel valve 568 can be controlled (e.g., by controller 380). In some examples, the controller 380 may cause the auxiliary parallel valve 568 to be actuated (e.g., opened and/or closed) based on sensor data received from one or more sensors. The second fluid output from the auxiliary parallel valve 568 may be combined with fluid output from the parallel valve 548, in some embodiments.

In some embodiments, system 500A includes LP selector valve 563. The LP selector valve 563 may receive gas output from the flash tank 413 via a first port and/or fluid output from the flash gas valve 420, the evaporator 318 via a second port. The LP selector valve 563 may direct the gas flow and/or the fluid flow toward the LP booster 314 via a third port. In some embodiments, the LP selector valve 563 is controllable. In some examples, a user (e.g., an engineer, an operator, a technician, etc.) may cause the LP selector valve 563 to actuate (e.g., may cause the first, second, and/or third ports to open or close), and/or the controller 380 may cause the LP selector valve 563 to actuate. In some embodiments, the controller 380 causes the LP selector valve 563 to actuate based on sensor data received. In some embodiments, the LP selector valve 563 receives the gas flow from the flash tank 413 via the first port and directs the gas flow toward the LP booster 314 via the third port while the second port is closed. In some embodiments, the LP selector valve 563 receives the flow of fluid from upstream of the compressor 322 via the second port and directs the fluid flow toward the LP booster via the third port while the first port is closed. In some embodiments, the LP selector valve 563 may allow the suction of flow from the suction side of compressor 322 when there is not enough flash gas available in the flash tank 413. The LP selector valve 563 may be provided with fluid from the flash tank 413 and/or the suction side of compressor 322 (e.g., the outlet side of evaporator 318, etc.)

Referring to FIG. 5B, a schematic diagram of a datacenter cooling system 500B including a PX 310 is shown, according to certain embodiments. In some embodiments, features that have reference numbers that are similar to reference numbers in other figures include similar properties, structures, and/or functionality as those described in other figures. In some examples, features of system 500B have similar properties, structures, and/or functionality as systems 300A-300C of FIGS. 3A-3C, system 400 of FIG. 4, and system 500A of FIG. 5A. In some embodiments, system 500B can include any of server room 390A, 390B, and/or 390C as illustrated in FIGS. 3A-3C.

In some embodiments, system 500B includes an air handling unit 599. Air handling unit 599 may receive a flow of warm air 398 and may direct the warm air to the evaporator 318 along a flow path of an air loop 587. In some embodiments, warm air is cooled (e.g., by refrigerant) in evaporator 318. The cooled air may be provided to the air handling unit 599. In some embodiments, a network of ducting directs air 398 between the air handling unit 599 and the evaporator 318. In some embodiments, the air 398 is passed through a filter 595 within the air handling unit 599. The filter 595 may be a particulate filter to filter contaminants from the air 398. In some embodiments, a fan 592 blows the cool air from the air handling unit 599 into the server room 390B. In some embodiments, multiple fans are used to move the air 398.

Referring to FIG. 5C, a schematic diagram of a datacenter cooling system 500C including a PX 310 is shown, according to certain embodiments. In some embodiments, features that have reference numbers that are similar to reference numbers in other figures include similar properties, structures, and/or functionality as those described in other figures. In some examples, features of system 500C have similar properties, structures, and/or functionality as systems 300A-300C of FIGS. 3A-3C, system 400 of FIG. 4, and systems 500A-500B of FIGS. 5A-5B. In some embodiments, system 500C can include any of server room 390A, 390B, and/or 390C as illustrated in FIGS. 3A-3C.

In some embodiments, system 500C includes an auxiliary gas cooler 566 that receives fluid output from the HP outlet of the PX 310 (e.g., second fluid at the fourth pressure). In some embodiments, heat is rejected from the fluid output from the HP outlet of the PX 310 via the auxiliary gas cooler 566. In some embodiments, an auxiliary high pressure valve 569 controls flow of fluid through the auxiliary gas cooler 566 and thus controls the flow of fluid output from the HP outlet of the PX 310. In some embodiments, as the fluid loses heat in the auxiliary gas cooler 566, the fluid may decrease in temperature. The fluid may be combined with fluid output from the LP outlet of the PX 310 and provided to the flash tank 413. In some embodiments, by including the auxiliary gas cooler 566, the high pressure booster (e.g., high pressure booster 324) can be eliminated from the system while maintaining the same functionality. Elimination of the high pressure booster may lead to decreased cost and maintenance (e.g., due to a decreased number of moving parts and/or components, etc.), and increased reliability of the system.

In some embodiments, fluid flowing out of the gas cooler 329 passes through a sub-cooling heat exchanger 530. In some embodiments, the fluid is sub-cooled (e.g., cooled to a temperature below the saturation temperature) so that the fluid transitions to an at least partially liquid state. Upon exiting the sub-cooling heat exchanger 530, a first sub-portion of the fluid is provided to the HP inlet of the PX 310 (e.g., the first fluid at the first pressure). A second sub-portion of the fluid is provided to the sub-cooling heat exchanger 530 to cool the fluid flowing from the gas cooler 329. The second sub-portion of the fluid may pass through a bypass high pressure valve 549. In some embodiments, second sub-portion of the fluid expands and/or decreases temperature when flowing through the bypass high pressure valve 549. In some embodiments, the bypass high pressure valve 549 is actuatable. Actuation of the bypass high pressure valve 549 may be controlled by the controller 380 (e.g., based on sensor data, etc.). The second sub-portion of fluid may be provided to the LP inlet of the PX 310 (e.g., the second fluid at the second pressure). In some embodiments, by including the sub-cooling heat exchanger 530, the low pressure booster (e.g., low pressure booster 314) can be eliminated from the system while maintaining the same functionality. Elimination of the low pressure booster may lead to decreased power demand, decreased maintenance (e.g., due to a decreased number of moving parts and/or components, etc.), and increased reliability of the system.

Referring to FIG. 5D, a schematic diagram of a datacenter cooling system 500D including a PX 310 is shown, according to certain embodiments. In some embodiments, features that have reference numbers that are similar to reference numbers in other figures include similar properties, structures, and/or functionality as those described in other figures. In some examples, features of system 500D have similar properties, structures, and/or functionality as systems 300A-300C of FIGS. 3A-3C, system 400 of FIG. 4, and systems 500A-500C of FIGS. 5A-5C. In some embodiments, system 500D can include any of server room 390A, 390B, and/or 390C as illustrated in FIGS. 3A-3C.

In some embodiments, system 500D includes an auxiliary flash tank 514. Auxiliary flash tank 514 may be a receiver (e.g., a receiver tank, etc.) to receive a flow of fluid from gas cooler 329 and/or auxiliary gas cooler 565. The auxiliary flash tank 514 may receive second fluid output from the second outlet of the PX 310 (e.g., via auxiliary gas cooler 565 and auxiliary parallel valve 568). In some embodiments, the auxiliary flash tank 514 may maintain a pressure difference (e.g., a small pressure difference, 10 psi, 20 psi, 30 psi, 40 psi, 50 psi, etc.) between the auxiliary flash tank 514 and the primary flash tank 413. The pressure difference between flash tanks may drive the flow of fluid through the low pressure inlet port of the PX 310 towards the low pressure outlet port of PX 310 and may thus perform the function of a low pressure booster (e.g., low pressure booster 314). Fluid from gas cooler 329 may pass through sub-cooling heat exchanger 530 and/or parallel valve 548 before entering auxiliary flash tank 514. In some embodiments, the sub-cooling heat exchanger 530 exchanges heat between a portion of the flow of fluid output from the gas cooler 329 and the flow of fluid output from the LP outlet of PX 310. In some embodiments, the fluid output from the LP outlet of the PX 310 is sub-cooled in the sub-cooling heat exchanger 530. In some embodiments, fluid output from the LP outlet of the PX 310 flows through a first low pressure valve 517 downstream from the sub-cooling heat exchanger 530. The first low pressure valve 517 may be actuatable (e.g., by a technician, an engineer, controller 380, etc.) to control the flow of fluid.

Fluid from auxiliary gas cooler 565 may pass through auxiliary parallel valve 568 before entering auxiliary flash tank 514. In some embodiments, fluid separates into gas and liquid inside auxiliary flash tank 514. The gas collected in auxiliary flash tank 514 may be provided to the LP inlet of PX 310 (e.g., second fluid at the second pressure). The liquid collected in the auxiliary flash tank 514 may flow out of the auxiliary flash tank 514, through a second low pressure valve 519, and into the flash tank 413. In some embodiments, the liquid is combined with fluid output from the LP outlet of the PX 310 (e.g., the first fluid at the third pressure). The second low pressure valve 519 may be actuatable (e.g., by a technician, an engineer, controller 380, etc.) to control the flow of fluid. In some embodiments, by including the auxiliary flash tank 514, the low pressure booster (e.g., low pressure booster 314) can be eliminated from the system while maintaining the same functionality. Elimination of the low pressure booster may lead to decreased power demand, decreased maintenance (e.g., due to a decreased number of moving parts and/or components, etc.), decreased cost and increased reliability of the system.

Referring to FIG. 5E, a schematic diagram of a datacenter cooling system 500E including a PX 310 is shown, according to certain embodiments. In some embodiments, features that have reference numbers that are similar to reference numbers in other figures include similar properties, structures, and/or functionality as those described in other figures. In some examples, features of system 500E have similar properties, structures, and/or functionality as systems 300A-300C of FIGS. 3A-3C, system 400 of FIG. 4, and systems 500A-500D of FIGS. 5A-5D.

In some embodiments, the refrigeration system/cycle of system 500E may be substantially similar to that of system 500C. However, in some embodiments, system 500E includes first cooling loop 386 and CRAC 391 inside the server room to cool air 398 for cooling servers in racks 399. In some embodiments, system 500E may include any of server rooms 390A, 390B, and/or 390C.

Referring to FIG. 5F, a schematic diagram of a datacenter cooling system 500F including a PX 310 is shown, according to certain embodiments. In some embodiments, features that have reference numbers that are similar to reference numbers in other figures include similar properties, structures, and/or functionality as those described in other figures. In some examples, features of system 500F have similar properties, structures, and/or functionality as systems 300A-300C of FIGS. 3A-3C, system 400 of FIG. 4, and systems 500A-500E of FIGS. 5A-5E.

In some embodiments, the refrigeration system/cycle of system 500F may be substantially similar to that of system 500D. However, in some embodiments, system 500F includes first cooling loop 386 and CRAC 391 inside the server room to cool air 398 for cooling servers in racks 399. In some embodiments, system 500E may include any of server rooms 390A, 390B, and/or 390C. In some embodiments, system 500F includes second cooling loop 370 to reject heat from the servers to the ambient environment via cooling tower 374.

FIG. 6 is a flow diagram illustrating a method 600 for controlling a datacenter cooling system (e.g., one or more of systems 300A-C of FIGS. 3A-3C), according to certain embodiments. In some embodiments, method 600 is performed by processing logic that includes hardware (e.g., circuitry, dedicated logic, programmable logic, microcode, processing device, etc.), software (such as instructions run on a processing device, a general purpose computer system, or a dedicated machine), firmware, microcode, or a combination thereof. In some embodiments, method 600 is performed, at least in part, by a controller (e.g., controller 180 of FIGS. 1A-1B, controller 380 of FIGS. 3A-3C, etc.). In some embodiments, a non-transitory storage medium stores instructions that when executed by a processing device (e.g., of controller 180 of FIGS. 1A-1B, controller 380 of FIGS. 3A-3C, etc.), cause the processing device to perform method 600.

For simplicity of explanation, method 600 is depicted and described as a series of operations. However, operations in accordance with this disclosure can occur in various orders and/or concurrently and with other operations not presented and described herein. Furthermore, in some embodiments, not all illustrated operations are performed to implement method 600 in accordance with the disclosed subject matter. In addition, those skilled in the art will understand and appreciate that method 600 could alternatively be represented as a series of interrelated states via a state diagram or events.

At block 602, processing logic causes, via a first heat exchanger (e.g., evaporator 318), heat to be exchanged between a first cooling loop and a refrigeration system. In some embodiments, the first cooling loop is a datacenter cooling loop to cool servers in a server room.

At block 604, processing logic causes, via the first cooling loop (e.g., cooling loop 386), multiple servers in the datacenter to be cooled. In some embodiments, the first cooling loop is caused to provide cooled coolant (e.g., water, a water-glycol mixture, etc.) to a CRAC (e.g., CRAC 391) in the server room. The CRAC may be caused to cool air circulating in the server room. A cooling coil of the CRAC may cool air in the server room to cool the servers. The servers may warm the air in the server room and the warmed air may be routed to the CRAC. Heat from the servers may be provided to the first cooling loop (e.g., via the cooling coil of the CRAC). The heat from the servers may be exchanged between the first cooling loop and the refrigeration system (e.g., at block 602).

At block 606, processing logic causes, via a pressure exchanger (e.g., PX 310), pressure to be exchanged between a first fluid of the refrigeration system and a second fluid of the refrigeration system. In some examples, processing logic (e.g., of controller 380) may cause a pressure exchanger to operate to exchange pressure between the first fluid and the second fluid. Specifically, processing logic may cause one or more valves to open and one or more pumps and/or compressors to provide the first fluid and the second fluid to inlets of the pressure exchanger. Processing logic may cause a compressor and/or a booster (e.g., LP booster 314) to flow the first fluid and the second fluid (respectively) to the pressure exchanger based on sensor data (e.g., temperature sensor data, pressure sensor data, flowrate sensor data, etc.). The first fluid may be provided to a first inlet of the pressure exchanger at a first pressure and the second fluid may be provided to a second inlet of the pressure exchanger at a second pressure. The first pressure may be higher than the second pressure. In some embodiments (e.g., in embodiments where the pressure exchanger is a rotary pressure exchanger), processing logic may cause a motor to turn a rotor of the pressure exchanger. Providing the first and second fluids to the inlets of the pressure exchanger via the compressor and/or booster, and/or turning the rotor of the pressure exchanger via a motor may cause pressure to be exchanged between the first and second fluids. The first fluid may exit the pressure exchanger via a first outlet at a third pressure and the second fluid may exit the pressure exchanger via a second outlet at a fourth pressure. The third pressure may be lower than the fourth pressure.

At block 608, processing logic causes, via a second heat exchanger (e.g., gas cooler 329), heat to be exchanged between the refrigeration system and a second cooling loop (e.g., cooling loop 370). In some embodiments, the refrigeration system provides heat (e.g., the heat from the servers cooled at block 604) from the first heat exchanger to the second heat exchanger.

At block 610, processing logic causes, via a cooling tower (e.g., cooling tower 374), rejection of heat from the second cooling loop to an ambient environment. In some embodiments, a cooling tower receives the coolant of the second cooling loop and cools the coolant by rejecting the heat to the ambient environment. The ambient environment may be an environment outside the refrigeration system and/or outside the datacenter. In some embodiments, a chiller unit is used to reject the heat to the ambient environment.

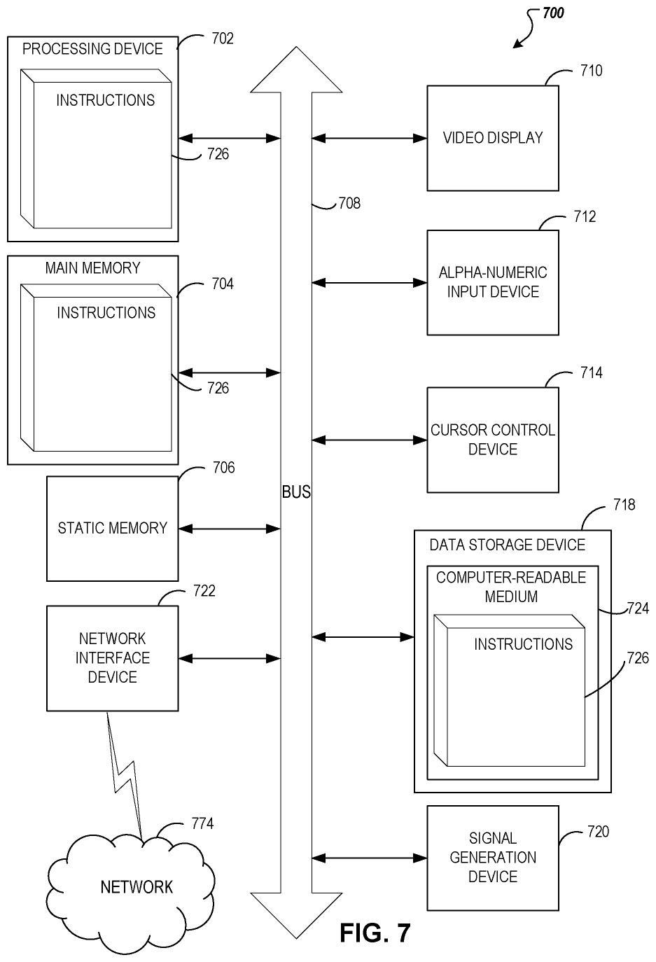

FIG. 7 is a block diagram illustrating a computer system 700, according to certain embodiments. In some embodiments, the computer system 700 is a client device. In some embodiments, the computer system 700 is a controller device (e.g., server, controller 180 of FIGS. 1A-1B, controller 380 of FIGS. 3A-3C, 4, and 5A-F).

In some embodiments, computer system 700 is connected (e.g., via a network, such as a Local Area Network (LAN), an intranet, an extranet, or the Internet) to other computer systems. Computer system 700 operates in the capacity of a server or a client computer in a client-server environment, or as a peer computer in a peer-to-peer or distributed network environment. In some embodiments, computer system 700 is provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein.

In some embodiments, the computer system 700 includes a processing device 702, a volatile memory 704 (e.g., Random Access Memory (RAM)), a non-volatile memory 706 (e.g., Read-Only Memory (ROM) or Electrically-Erasable Programmable ROM (EEPROM)), and/or a data storage device 716, which communicates with each other via a bus 708.

In some embodiments, processing device 702 is provided by one or more processors such as a general purpose processor (such as, in some examples, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, in some examples, an Application Specific Integrated Circuit (ASIC), a Field Programmable Gate Array (FPGA), a Digital Signal Processor (DSP), or a network processor). In some embodiments, processing device 702 is provided by one or more of a single processor, multiple processors, a single processor having multiple processing cores, and/or the like.

In some embodiments, computer system 700 further includes a network interface device 722 (e.g., coupled to network 774). In some embodiments, the computer system 700 includes one or more input/output (I/O) devices. In some embodiments, computer system 700 also includes a video display unit 710 (e.g., a liquid crystal display (LCD)), an alphanumeric input device 712 (e.g., a keyboard), a cursor control device 714 (e.g., a mouse), and/or a signal generation device 720.

In some implementations, data storage device 718 (e.g., disk drive storage, fixed and/or removable storage devices, fixed disk drive, removable memory card, optical storage, network attached storage (NAS), and/or storage area-network (SAN)) includes a non-transitory computer-readable storage medium 724 on which stores instructions 726 encoding any one or more of the methods or functions described herein, and for implementing methods described herein.

In some embodiments, instructions 726 also reside, completely or partially, within volatile memory 704 and/or within processing device 702 during execution thereof by computer system 700, hence, volatile memory 704 and processing device 702 also constitute machine-readable storage media, in some embodiments.

While computer-readable storage medium 724 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

The methods, components, and features described herein may be implemented by discrete hardware components or may be integrated in the functionality of other hardware components such as ASICS, FPGAs, DSPs or similar devices. In addition, the methods, components, and features may be implemented by firmware modules or functional circuitry within hardware devices. Further, the methods, components, and features may be implemented in any combination of hardware devices and computer program components, or in computer programs.

Unless specifically stated otherwise, terms such as “actuating,” “adjusting,” “causing,” “controlling,” “determining,” “identifying,” “providing,” “receiving,” “regulating,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. Also, the terms “first,” “second,” “third,” “fourth,” etc. as used herein are meant as labels to distinguish among different elements and may not have an ordinal meaning according to their numerical designation.

Examples described herein also relate to an apparatus for performing the methods described herein. This apparatus may be specially constructed for performing the methods described herein, or it may include a general purpose computer system selectively programmed by a computer program stored in the computer system. Such a computer program may be stored in a computer-readable tangible storage medium.

The methods and illustrative examples described herein are not inherently related to any particular computer or other apparatus. Various general purpose systems may be used in accordance with the teachings described herein, or it may prove convenient to construct more specialized apparatus to perform methods described herein and/or each of their individual functions, routines, subroutines, or operations. Examples of the structure for a variety of these systems are set forth in the description above.

The preceding description sets forth numerous specific details, such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about,” “substantially,” or “approximately” is used herein, this is intended to mean that the nominal value presented is precise within ±10%. Also, the terms “first,” “second,” “third,” “fourth,” etc. as used herein are meant as labels to distinguish among different elements and can not necessarily have an ordinal meaning according to their numerical designation.

The terms “over,” “under,” “between,” “disposed on,” and “on” as used herein refer to a relative position of one material layer or component with respect to other layers or components. In some examples, one layer disposed on, over, or under another layer may be directly in contact with the other layer or may have one or more intervening layers. Moreover, one layer disposed between two layers may be directly in contact with the two layers or may have one or more intervening layers. Similarly, unless explicitly stated otherwise, one feature disposed between two features may be in direct contact with the adjacent features or may have one or more intervening layers.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner. In one embodiment, multiple metal bonding operations are performed as a single step.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which each claim is entitled.

What is claimed is:

1. A system comprising:
a refrigeration system to exchange heat between a first cooling loop and a second cooling loop, wherein the first cooling loop is configured to cool a plurality of servers of a datacenter, wherein the second cooling loop is configured to provide heat to a cooling tower to reject the heat to an ambient environment, and wherein the refrigeration system comprises:
a pressure exchanger (PX) configured to receive a first fluid at a first pressure via a first inlet of the PX, receive a second fluid at a second pressure via a second inlet of the PX, and exchange pressure between the first fluid and the second fluid, wherein the first fluid is to exit the PX at a third pressure via a first outlet of the PX, and wherein the second fluid is to exit the PX at a fourth pressure via a second outlet of the PX;
a first heat exchanger configured to exchange first heat between the first cooling loop and at least a portion of the first fluid output from the first outlet of the PX; and
a second heat exchanger configured to exchange second heat between at least a portion of the first fluid that is to enter the first inlet of the PX and the second cooling loop.

2. The system of claim 1, wherein the first heat exchanger comprises an evaporator of the refrigeration system configured to cause the at least a portion of the first fluid output from the first outlet of the PX to transition from a liquid state to a vapor state.

3. The system of claim 1, wherein the second heat exchanger comprises a gas cooler of the refrigeration system configured to cool the at least a portion of the first fluid.

4. The system of claim 1, wherein the first fluid and the second fluid comprise carbon dioxide (CO₂), wherein the first pressure is higher than the second pressure, and wherein the third pressure is lower than the fourth pressure.

5. The system of claim 1, wherein the refrigeration system further comprises:
an auxiliary heat exchanger configured to receive the second fluid output from the second outlet of the PX and exchange third heat from the second fluid with the ambient environment.

6. The system of claim 5, wherein the refrigeration system further comprises:
a valve configured to receive the second fluid from the auxiliary heat exchanger and regulate flow of the second fluid to a receiver.

7. The system of claim 1, wherein the refrigeration system further comprises:
a third heat exchanger configured to exchange third heat between at least the at least a portion of first fluid that is to enter the first inlet of the PX and a sub-portion of fluid output from the third heat exchanger to sub-cool the at least a portion of the first fluid that is to enter the first inlet of the PX.

8. The system of claim 7, wherein the refrigeration system further comprises:
a booster configured to:
receive the second fluid output from the PX at the fourth pressure;
increase pressure of the second fluid; and
provide the second fluid upstream from an inlet of the second heat exchanger.

9. The system of claim 1, wherein the refrigeration system further comprises:
a first receiver configured to receive the first fluid from the first outlet of the PX, wherein the receiver forms a chamber configured to separate the first fluid into a first gas and a first liquid.

10. The system of claim 9, wherein the refrigeration system further comprises:
a booster configured to:
receive a portion of the first gas from the first receiver;
increase pressure of the portion of the first gas to form the second fluid at the second pressure; and
provide the second fluid at the second pressure to the PX via the second inlet.

11. The system of claim 8, wherein the refrigeration system further comprises:
a second receiver configured to receive the second fluid output from the second outlet of the PX and to provide at least a portion of the second fluid output from the second outlet of the PX to the second inlet of the PX as the second fluid at the second pressure.

12. The system of claim 1, wherein the refrigeration system further comprises:
a compressor configured to receive at least a portion of the first fluid output from the first heat exchanger, increase a corresponding pressure of the at least a portion of the first fluid, and provide the at least a portion of the first fluid to the second heat exchanger.

13. The system of claim 1, further comprising:
a cooler unit configured to exchange third heat between the first cooling loop and air circulating in the datacenter to cool the plurality of servers.

14. The system of claim 13, further comprising:
a pump configured to pump coolant along the first cooling loop between the first heat exchanger and the cooler unit.

15. The system of claim 13, wherein the cooler unit comprises a cooling coil configured to receive coolant from the first heat exchanger along the first cooling loop and exchange heat between the air in the datacenter and the coolant.

16. The system of claim 13, wherein the datacenter comprises a raised floor configured to support multiple server racks to support the plurality of servers, and wherein the air flows through the raised floor to the multiple server racks.

17. The system of claim 13, wherein the datacenter comprises ducting configured to direct heated air away from the plurality of servers and toward the cooler unit.

18. A system comprising:
a refrigeration system configured to cool a plurality of servers in a datacenter, wherein the refrigeration system comprises:
a pressure exchanger (PX) configured to receive a first fluid at a first pressure via a first inlet of the PX, receive a second fluid at a second pressure via a second inlet of the PX, and exchange pressure between the first fluid and the second fluid, wherein the first fluid is to exit the PX at a third pressure via a first outlet of the PX, and wherein the second fluid is to exit the PX at a fourth pressure via a second outlet of the PX;
a first heat exchanger configured to provide first heat from the plurality of servers to at least a portion of the first fluid output from the first outlet of the PX; and
a second heat exchanger configured to provide second heat from at least a portion of the first fluid that is to enter the first inlet of the PX to a cold sink.

19. The system of claim 18, wherein the first fluid and the second fluid comprise carbon dioxide (CO₂), wherein the first pressure is higher than the second pressure, and wherein the third pressure is lower than the fourth pressure.

20. The system of claim 18, wherein the first heat exchanger is configured to cool air circulating in the datacenter.

21. The system of claim 18, wherein the refrigeration system further comprises:
a receiver configured to receive the first fluid from the first outlet of the PX, wherein the receiver forms a chamber configured to separate the first fluid into a first gas and a first liquid; and
a booster configured to:
receive a portion of the first gas from the receiver;
increase pressure of the portion of the first gas to form the second fluid at the second pressure; and
provide the second fluid at the second pressure to the PX via the second inlet.

22. The system of claim 18, wherein the refrigeration system further comprises:
a compressor configured to receive at least a portion of the first fluid output from the second heat exchanger, increase a corresponding pressure of the at least a portion of the first fluid, and provide the at least a portion of the first fluid to the first heat exchanger, wherein the first heat exchanger is configured to provide the first fluid to the PX via the first inlet.

23. A system comprising:
a refrigeration system configured to cool a plurality of servers, wherein the refrigeration system comprises:
a pressure exchanger (PX) configured to receive a first refrigeration fluid at a first pressure via a first inlet of the PX, receive a second refrigeration fluid at a second pressure via a second inlet of the PX, and exchange pressure between the first refrigeration fluid and the second refrigeration fluid, wherein the first refrigeration fluid is to exit the PX at a third pressure via a first outlet of the PX, and wherein the second refrigeration fluid is to exit the PX at a fourth pressure via a second outlet of the PX;
a first heat exchanger configured to provide first heat from the plurality of servers to at least a portion of the first refrigeration fluid output from the first outlet of the PX; and
a second heat exchanger configured to remove second heat from at least a portion of the first refrigeration fluid that is to enter the first inlet of the PX.

24. The system of claim 23, wherein the first pressure is higher than the second pressure, and wherein the third pressure is lower than the fourth pressure.
